(19) United States
(12) Patent Application Publication
(10) Pub. No.: US 2011/0203637 A1
(43) Pub. Date: Aug. 25, 2011

(54) Efficient Installation Solar Panel Systems

(75) Inventors: John C. Patton, Granite Bay, CA (US); Todd Lindstrom, Auburn, CA (US); YangLin Li, ShenZhen City (CN); DaJiu He, Guangzhou (CN)

(73) Assignee: SOLAR POWER, INC., Roseville, CA (US)

(21) Appl. No.: 13/123,472

(22) PCT Filed: Oct. 10, 2009
(86) PCT No.: PCT/US09/60291

§ 371 Date: Apr. 8, 2011

Related U.S. Application Data
(60) Provisional application No. 61/195,780, filed on Oct. 11, 2008.
(60) Provisional application No. 61/208,323, filed on Feb. 23, 2009.
(60) Provisional application No. 61/214,857, filed on Apr. 28, 2009.

(51) Int. Cl. H01L 31/042; H01L 31/18; E04D 13/18

(52) U.S. Cl. 136/244; 29/890.033; 52/173.3

(57) ABSTRACT

An efficient solar panel system is mounted to a roof using various attachments and supports for solar panel modules (32) including elastic solar panel couplings (173), laterally fluidically constrained channels (5), solar panel roof mount brackets (130) having raised surfaces (21), suspended substantially rigid hollow rail components (63), and solar panel electrical penetration connectors (25) on solar panel roof mount constraints (101) in the various embodiments.

This is an international application claiming the benefit of U.S. Provisional Application No. 61/195,780 filed Oct. 11, 2008, Provisional Application No. 61/208,323 filed Feb. 23, 2009, and Provisional Application No. 61/214,857 filed Apr. 28, 2009, each hereby incorporated by reference in their entirety.

### TECHNICAL FIELD

This invention relates to the field of solar panel installation systems that are very easy to install, low cost, and permit coordinated installation even when accomplished by different persons. In various embodiments, solar collector PV module arrays can be attached to an adjustable support system, can be quickly installed into place, can enhance the seal of a roof, and can be properly connected electrically.

### BACKGROUND

The field of solar power has become very important. Solar power systems can be installed in huge seas as well as for individual residential and commercial usage. These individual systems can supply power to an underlying structure, and can also supply excess power into the grid or the like. For individual systems, it is not uncommon to locate these systems on the roofs of buildings or on some other surface.

In order to remain economic, it is not only important that individual solar panels or the like produce a significant amount of power, but it can also be important that both the materials and structures be reasonably priced, and that the actual installation be achieved quickly without too much difficulty. This is important because a solar collector PV module can be an array formed by a plurality of solar panels on a support system. This array can involve significant installation of numerous components such as solar panel modules. Further, a support system can be either secured to a surface such as to the roof rafters by a roof mount or to the roof oriented strand board (“OSB”), plywood or sheathing using a roof mount. This was typically accomplished by solar system installers so it can involve schedule and economic considerations.

The perspective of initial installation of the solar power system is also important in the overall economics of this field. For instance, while solar power systems are bought from manufacturers who frequently make individual components, a separate installer is frequently employed to actually site, locate, and connect collective of power componentry that makes a roof mount or other solar power system. Installers, of course, have differing degrees of capabilities. In addition, the initial cost of the system should not be increased significantly for simply the action of installing it on a pre-existing roof or other surface. Furthermore, the cost of the solar panels and other such componentry itself is significant enough that the cost of an underlying structure should not be so large as to greatly increase the cost of the overall system. As may be imagined, there is constant pressure to make underlying structures and indeed the entire solar power system less expensive. Beyond the cost of the system, the actual labor of installation is also in focus. The more time an installer needs to spend on a roof or other area installing individual componentry, the more expensive the overall system is to a user. Thus, it is desirable to reduce the cost of not only the componentry involved, but also to reduce the cost of the installation labor. This can occur, most significantly, by reducing the amount of the labor needed to achieve the installation. Thus, it is desirable to present solar power systems that take less time to install, that cost less to purchase, and that allows the most economic use of labor.

Details of installation can be important because any leakage through a roof or the like can be disastrous and because proper electrical connections can be critical to proper operation. It is desired to make any roof mounting compatible with existing roof materials ranging from composition (asphalt shingle) roofs to even tile or metal shingle roof materials. Designs to withstand high load conditions or building requirements can be important. A desire that has existed for some time is to be able to allow persons to support and even achieve some of the installation needs without a need for specialized solar panel expertise. It has thus been desired to accommodate the possibility of less than perfectly aligned mounts for an end system that may need to be very precise. In addition a roofer's expertise in sealing a roof has been desired even though the installation of a solar panel system requires a different level of expertise or knowledge.

Several aspects can be important for an overall system. First, with respect to speed of installation, it can be important to allow installation of the numerous solar panel modules without a need for involved procedures, tooling, or equipment. Second, it can be important to provide a system that assuredly results in no impact to an existing or new roof seal. No one wants their roof to leak because they installed a solar system on that roof. Third, it can be important to provide a system that lets roofers do their processes and solar system installers do their processes independent of each other and to the degree each is most economic or best suited. Finally, even for the professional solar system installer, it can be important for safety and to confirm to government regulation and code that to make sure each of the numerous solar panel modules and structure are properly grounded.

### DISCLOSURE OF INVENTION

The present invention presents designs that can be implemented in various embodiments. These embodiments can meet a variety of needs ranging from efficient installation solar power systems to sealed and water deflection solar panel systems. In general, the invention involves the inclusion of flexible mounts, quick attachments, electrical attachments, sealing components, and water channeling to aid in both the installation of a system as well as creating a sealed environment of at least some of the attachment components that could cause roof leaks. Specific designs can involve a suspended solar power componentry support structure with perhaps shaped rails, sliding rails, sliding clamps, clickable clamps and the like to support solar panel components such as solar panel modules and the like. In various embodiments, designs can present piercable components for quick electrical attachment of solar panel components. The piercing components may include friction fasteners or perhaps even projection like components for pivoting action piercing.

Naturally, these and other aspects and goals are discussed in the following specification and claims.

### BRIEF DESCRIPTION OF THE DRAWINGS

FIG. 1 is a top view of an embodiment of solar panel modules attached to a support system.

FIG. 2 is a partial view of an embodiment of an end of a solar panel roof attachment rail on a roof.

FIG. 3 is a partial view of an alternative embodiment of an end of a solar panel roof attachment rail on a roof.

FIG. 4 is a cross-sectional view of an embodiment of a solar panel roof attachment rail.

FIG. 5 is a perspective cross-sectional view of an embodiment of a solar panel roof mount bracket, raised surface, and roof mount bracket screw.

FIG. 6 is a view of a cross-section of an embodiment of a solar panel roof mount bracket, raised surface, and roof mount bracket screw.

FIG. 7 is a perspective view of an embodiment of a set of solar panel roof attachment rails.

FIG. 8 is a partial perspective view of an embodiment of a solar panel roof mount constraint attached to a solar panel roof attachment rail.

FIG. 9 is a partial perspective view of an embodiment of a solar panel roof mount constraint attached to a solar panel roof attachment rail.

FIG. 10 is a partial perspective view of an embodiment of an elastic solar panel coupling attached to a rail slide element.

FIG. 11 is a partial side view of an embodiment of part of a solar panel module attached to a solar panel roof mount constraint.

FIG. 12 is a side view of an embodiment of a solar panel module attached to a support system.

FIG. 13 is partial side view of an embodiment of an end of a solar panel module sliding into an elastic solar panel coupling.

FIG. 14 is partial side view of an embodiment showing an end of a solar panel module attached to an elastic solar panel coupling.

FIG. 15 is a partial side view of an embodiment of latch between two solar panel modules.

FIG. 16 is a partial side view of an embodiment of a male connector and a spar for latching of solar panel modules.

FIG. 17 is a perspective view of an embodiment of a spar for latching of solar panel modules.

FIG. 18 is a perspective bottom view of an embodiment of a spar for latching of solar panel modules.

FIG. 19 is a two dimensional cross section of an embodiment of a spar and a frame.

FIG. 20 is an exploded view of FIG. 19 of a spar thread embodiment.

FIG. 21 is a cross section of an embodiment of a spar and frame.

FIG. 22 is a cross section of an embodiment of a spar and frame of FIG. 21 with the spar rotated 90 degrees.

FIG. 23 is a perspective view of an embodiment of a solar panel module snapped into a support system.

FIG. 24 is a perspective view of an embodiment of solar panel modules attached to elastic solar panel couplings.

FIG. 25 is a perspective view of an embodiment of solar panel modules attached to elastic solar panel couplings using spar tools.

FIG. 26 a partial view of an embodiment of solar panel modules attached to elastic solar panel couplings and latched using spar tools.

FIG. 27 a perspective view of an embodiment of solar panel modules attached to elastic solar panel couplings using spar tools after rotation of a spar.

FIG. 28 is a perspective view of a double elastic solar panel coupling embodiment.

FIG. 29 is a perspective view of a bottom of an elastic solar panel coupling embodiment.

FIG. 30 is a perspective view of a dual rail roof mount embodiment.

FIG. 31 is a partial perspective view of a dual rail roof mount embodiment.

FIG. 32 is a perspective view of an embodiment of two solar panel modules attached to a support system.

FIG. 33 is a partial view of an embodiment of a suspended substantially rigid hollow rail component.

FIG. 34 is a cross sectional view of an embodiment of a suspended substantially rigid hollow rail component attached to a rail mount.

FIG. 35 is a partial top view of an embodiment of a continuously adjustable roof mount support.

FIG. 36 is a side view of an embodiment of a continuously adjustable roof mount support with a slidable rail support.

FIG. 37 is an alternative side view of an embodiment of a continuously adjustable roof mount support with a slidable rail support.

FIG. 38 is a perspective view of an embodiment of suspended substantially rigid hollow rail component.

FIG. 39 is an end view of an embodiment of a continuously adjustable roof mount support and slidable rail support.

FIG. 40 is a perspective side view of an embodiment of an elastic solar panel coupling.

FIG. 41 is a partial view of an embodiment of two suspended substantially rigid hollow rail component attached together.

FIG. 42 is a partial perspective view of an embodiment of an end of a suspended substantially rigid hollow rail component and an interior continuous rail splice connector.

FIG. 43 is a top view of an embodiment of an end of a suspended substantially rigid hollow rail component and an interior continuous rail splice connector.

FIG. 44 is a perspective view of an embodiment of an interior continuous rail splice connector.

FIG. 45 is a perspective view of an embodiment of an increased surface friction fastener.

FIG. 46 is a perspective view of an embodiment of an attachment system using a roof mount layout.

FIG. 47 is a perspective view of an embodiment of a roof mount layout with solar panel roof attachment rails attached to roof mount supports.

### MODE(S) FOR CARRYING OUT THE INVENTION

The present invention includes a variety of aspects, which may be combined in different ways. The following descriptions are provided to list elements and describe some of the embodiments of the present invention. These elements are listed with initial embodiments, however it should be understood that they may be combined in any manner and in any number to create additional embodiments. The variously described examples and preferred embodiments should not be construed to limit the present invention to only the explicitly described systems, techniques, and applications. Further, this description should be understood to support and encompass descriptions and claims of all the various embodiments, systems, techniques, methods, devices, and applications with any number of the disclosed elements, with each element alone, and also with any and all various permutations and combinations of all elements in this or any subsequent application.

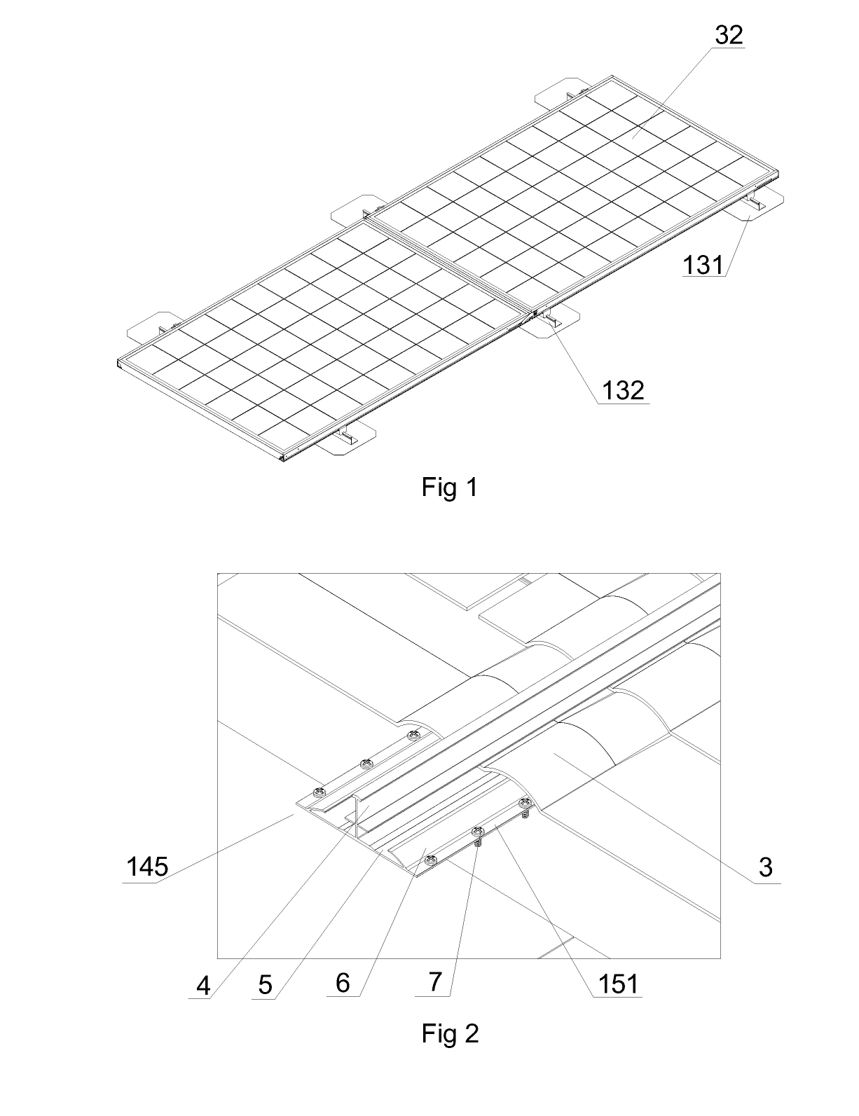

In general, FIG. 1 shows an embodiment of a solar panel support system which can be efficiently mounted to an area or surface such as a roof, pitch roof, flat roof, solid surface, ground, and the like at perhaps a low overall cost. Because the various embodiments of the invention may be used with different areas or surfaces, it is intended that any discussion of a roof or attachment to a roof is presented only as an example of an embodiment and is meant to include additional embodiments with any kind of area or surface having mountable capabilities including but not limited to a roof, pitch roof, flat roof, solid surface, ground, and the like. A solar collector PV array may be formed by a plurality of solar panels on a support system. The support system can be secured to roof rafters by a roof mount or perhaps even to the roof oriented strand plywood, plywood or sheathing using a rail mount.

With either the roof mount or rail mount, solar panel modules may be quickly snapped into place using various clamps on the mounts. The modules may also be locked together once put into place. The modules may be firmly held to the mounts and to each other forming a strong rigid solar panel array on a surface such as a roof. Many different assembly steps previously needed may be combined by the present invention to make the solar panel installation simple and fast.

A roof mount may be used for existing composition roofs, such as but not limited to asphalt shingle roof and the like, high load conditions or perhaps even to meet building requirements. A PV system of the present invention may also be used with tile roofs by perhaps putting a PV system over a composition roof and building a tile around the PV system. This may make for an attractive PV system inset within the tile.

In particular to FIG. 1, an embodiment of a roof mount supporting an array of solar panel modules (32) is shown. It can be understood that a roof mount may be attached to a surface such as roof or the like. As explained earlier a roof mount or a rail mount may be used in a solar panel support system. Various types of clamps may be connected to the roof mounts or rail mounts for attachment of solar panel modules. Any connected components or connection between components described herein are meant to include either or both a direct connection or an indirect connection. An indirect connection may have at least one or more elements in connection between the components.

Specifically, solar panel modules may be snapped into place using various clamps on mounts that are attached to a roof. The mounts can either be roof mounts that may be attached to the roof rafters or the like or they can be rail mounts that may be attached to the roof rafters or roof sheathing such as but not limited to plywood, oriented strand board wood plank, or the like. Solar panel module installation may be fast since the solar panel modules may easily and quickly attach onto the mounts using standard modules. The modules can be snapped into place either in landscape or portrait orientation.

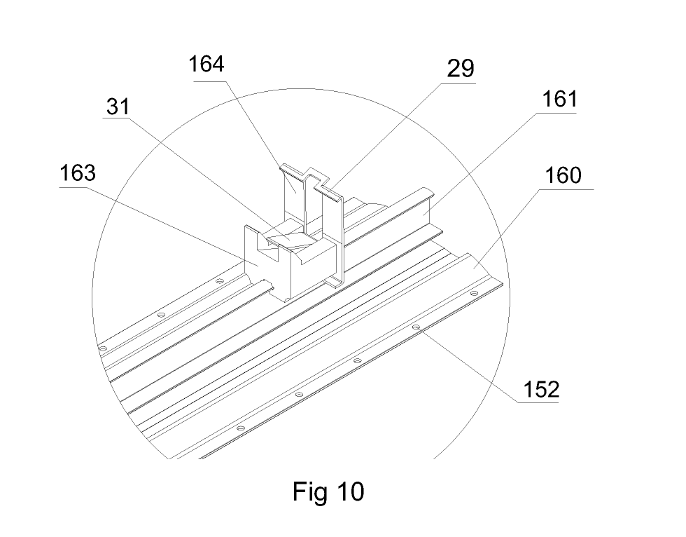

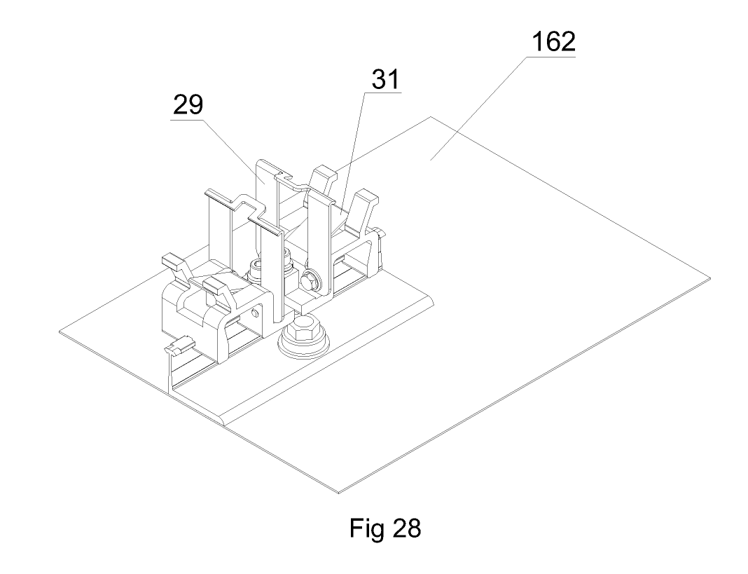

For example, the present invention may provide, in embodiments, a plurality of solar module anchors (160) secured to an area (162), a plurality of elastic solar panel couplings (163) connected to the solar module anchors, and a plurality of solar panel modules (32) elastically attached to the elastic solar panel couplings (163) as may be shown in FIGS. 10 and 28. One could efficiently install a modularized solar power system by completing the steps of securing a plurality of solar module anchors (160) to an area (162), providing a plurality of solar panel modules (32), and completely elastically attaching the solar panel modules.

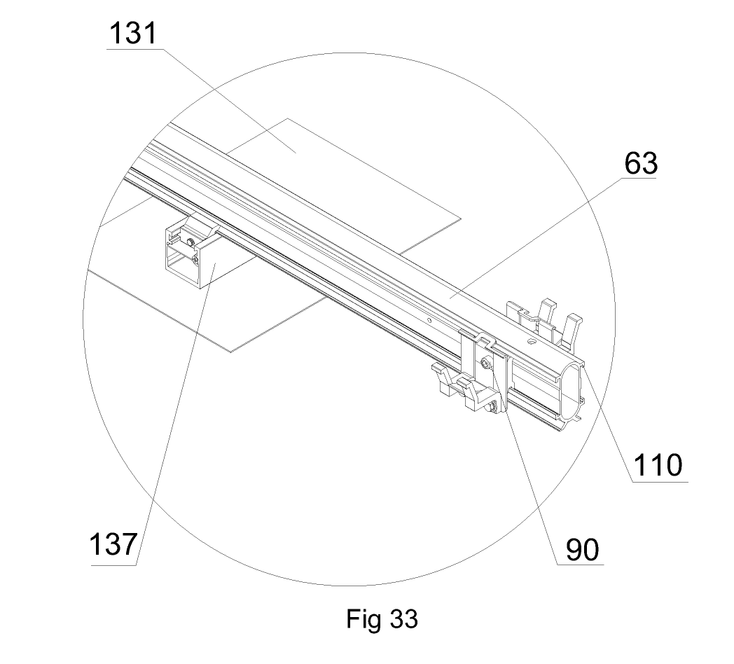

A solar module anchor may be any kind of component which can be connected to an area and is capable of supporting elastic solar panel couplings. As shown in FIG. 10, a solar module anchor (160) may be a type of rail mount. Other embodiments may provide that a solar module anchor may be a type of roof mount perhaps with an internal railing component or perhaps even with a separate attachable railing component or the like. A solar module anchor may include a rail slide element (161) as may be understood in FIG. 10. A rail slide element may be any type of configuration which may allow sliding movement along a rail. For example, an elastic solar panel coupling (163) may be attached to a rail slide element of a solar module anchor and may be capable of rail sliding along the rail slide element. This may provide flexibility in aligning up the anchors for solar panel attachment. A fastener (90) such as shown in FIG. 33 may be provided to fasten a rail slide element. Fasteners may include any of various devices for fastening including but not limited to screws, clips, snaps, bolts, clasps, locks, latches, rivets, holders, and the like. In one embodiment, a fastener (90) may secure a clamp, coupling or the like to a rail with a rail slider fastener which, in embodiments, may be a back screw for securing any slidable components into a secure position therefore back screwing slidable components to ultimately secure a solar panel module to an attachment system.

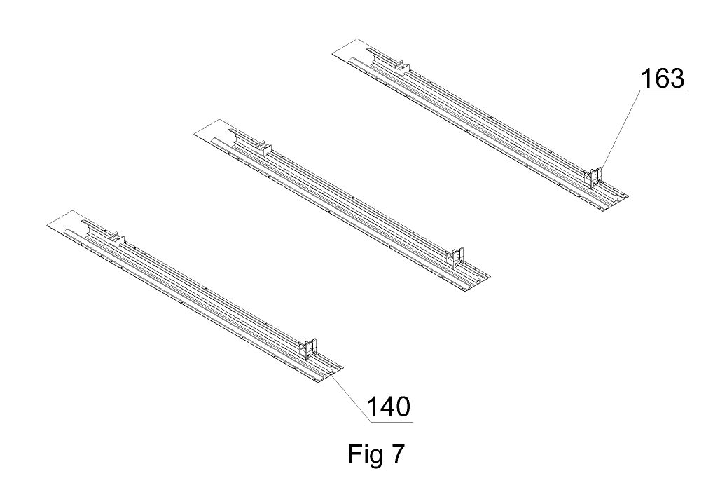

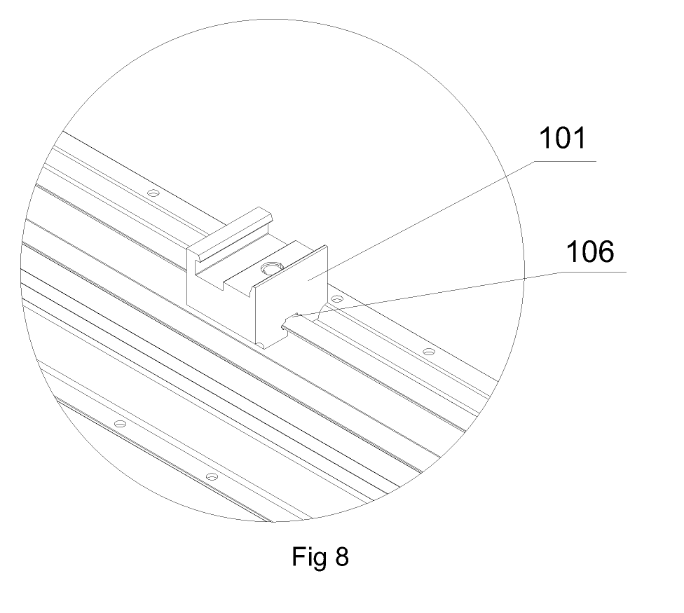

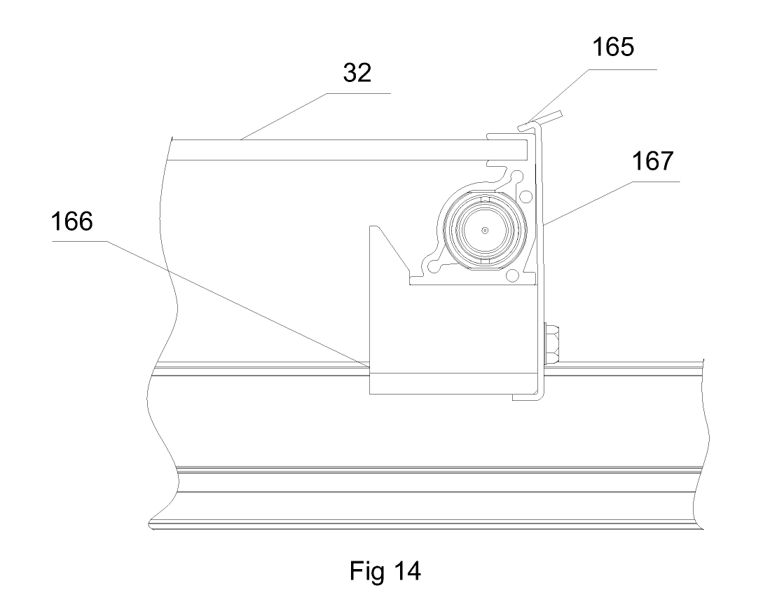

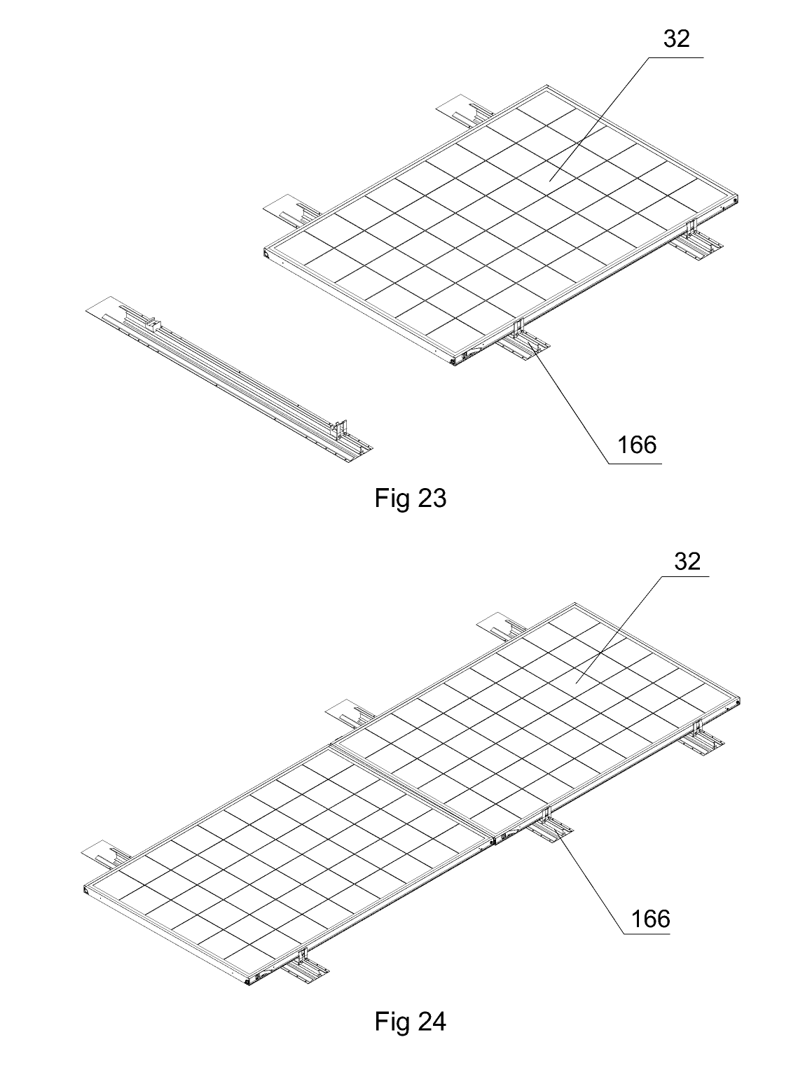

Elastic solar panel couplings may include any type of solar panel clamp which may be accommodating to a solar panel module and capable of returning to perhaps its original shape. Elastic solar panel couplings (163) may be a direct connector between a solar module anchor and a solar panel module thus they can provide direct solar panel connecting of solar panel modules. An example of one embodiment of an elastic solar panel coupling (163) is shown in FIGS. 7 and 10. In embodiments, a rail mount (166), as shown in FIG. 23, may be connected to an elastic solar panel coupling. A rail mount may be a component configured to mount to a rail as shown in the example in FIG. 14 to allow rail mounting of a rail. A vertical retainer (167) may also be provided for vertically retaining of a solar panel module. In embodiments, a vertical retainer (167) may be a side flex retainer which side flex retains the solar panel modules. Therefore, in embodiments, an elastic solar panel coupling may be dualy capable of clamping a solar panel module and attachment to a mount anchor.

When installing solar panel modules, an installer may have to place the solar panel into a support system and then secure the solar panel into position. This securement may be the placement and tightening of a screw, it may be the placement of a locking component, or the like. To increase efficiency of the system, embodiments of the invention provide that an elastic solar panel coupling (163) may be a complete elastic constraint of a solar panel module so that in perhaps one step, a solar panel module may be completely elastically attached to or even completely elastically constrained in a solar panel support system.

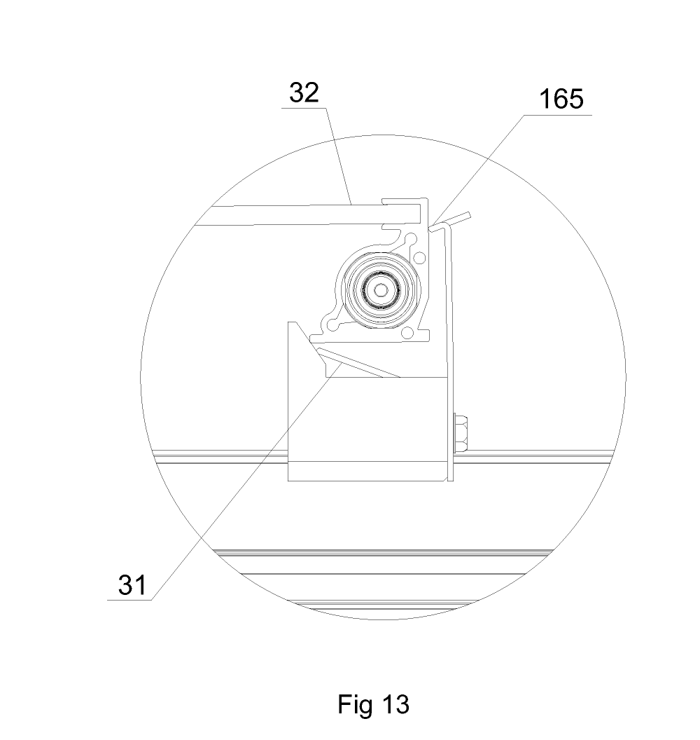

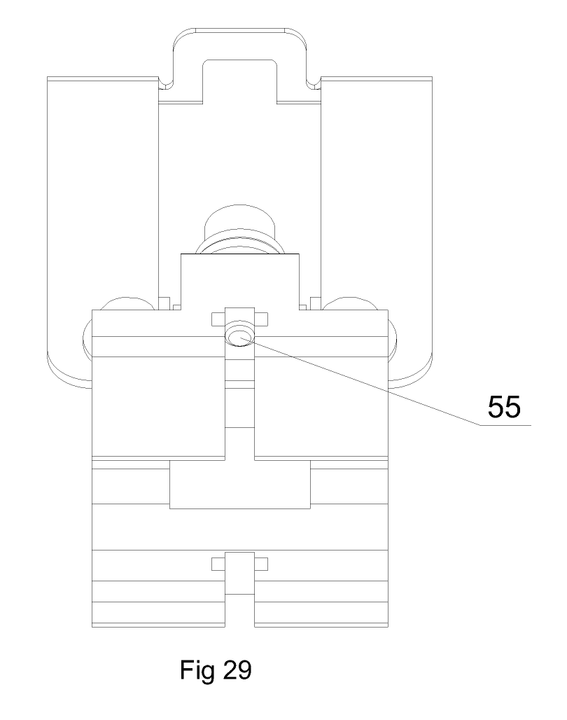

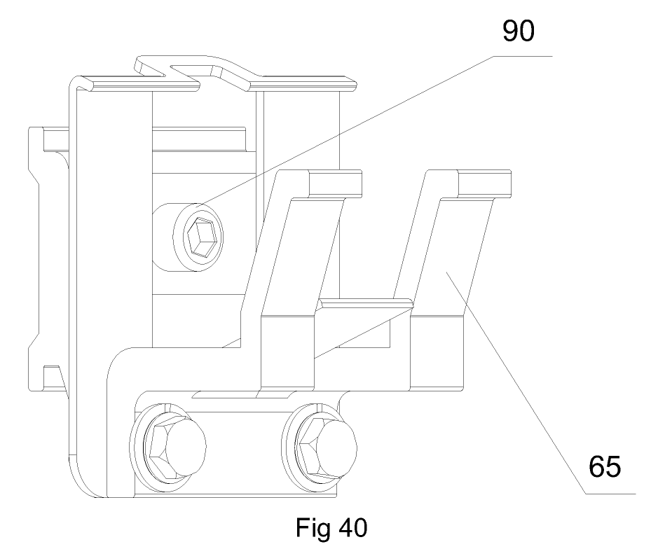

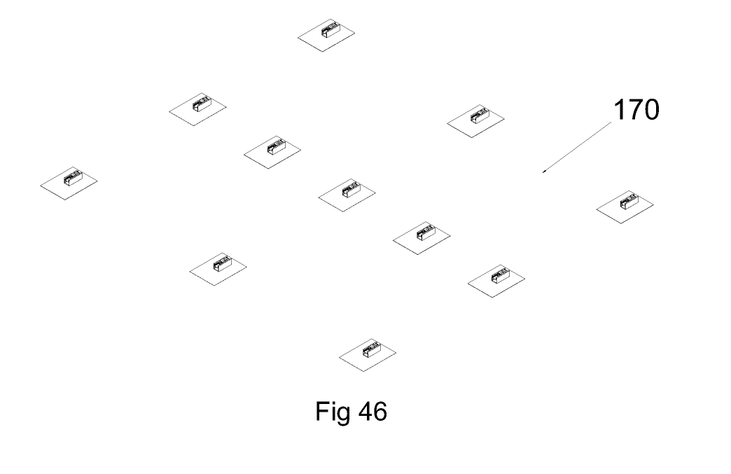

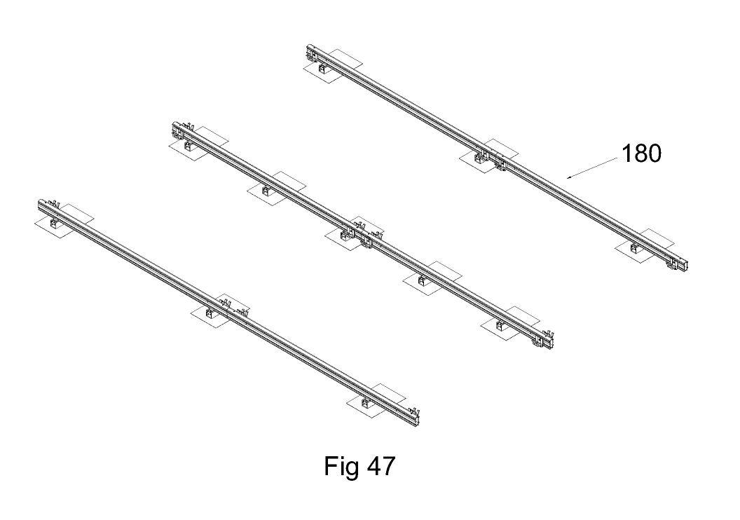

FIG. 40 shows an embodiment of an elastic solar panel coupling and an edge positioner (65) attached to the coupling. A solar panel module may be edgingly positioned in an elastic solar panel coupling by action of an attachment system. In embodiments, an attachment system (170) can be any solar panel support framework for attachment of a solar panel module, or perhaps part of or an edge of a solar panel module, to an area such as that embodied in FIGS. 46 and 47 and including but not limited to mounts, rails, clamps, couplings, supports or the like. FIG. 46 shows an attachment system of an arrangement of roof mounts (170) and FIG. 47 shows a rail mounted attachment system (180). Of course, many other alternative embodiments may be used in an attachment system including but not limited to the solar panel roof attachment rails (140) in the embodiment shown in FIG. 7 as discussed herein or the like. As a solar panel module (32) may be placed in an elastic solar panel coupling, an edge positioner (65) may place part of the solar panel module in an appropriate position to allow the solar panel module to engage with the coupling. A part of a solar panel module may include the solar panel module itself, a frame of the solar panel module, an end or an edge of a solar panel module, and the like. In embodiments, an edge positioner (65) can be an integral clip edge positioner which may provide that the edge positioner is an integral part attached to the coupling. In other embodiments, a slide positioner (31) may be included in an elastic solar panel coupling. One embodiment of a slide positioner may be shown in FIGS. 10, 13 and 28 perhaps acting to move part or even an edge of a solar panel module into a coupling by sliding the solar panel module into the coupling of an attachment system. In embodiments, this may include integrally edgingly retaining a solar panel module in an attachment system with an integral edge positioner. A slide positioner (31) may also act as an insertion bias element for insertion biasing a solar panel module when attached to a coupling of an attachment system. An insertion bias element may have a diagonal inclination and may even be an elastic tongue which can elastically respond to or even resist the solar panel module while being inserted. In some embodiments, the elastic tongue can be placed at a bottom of a coupling such as to perhaps assist in bottom raising a solar panel module as shown in FIG. 13. Further, a slide positioner may act as a clip opposing element in that it may function in an opposing manner against a vertical retainer (167) of a coupling. FIG. 29 shows a bottom of a spring clamp base screw (55) which may extend to a mount bracket and may lock the coupling into place and may even allow continuity for grounding between a base of a coupling and a mount bracket.

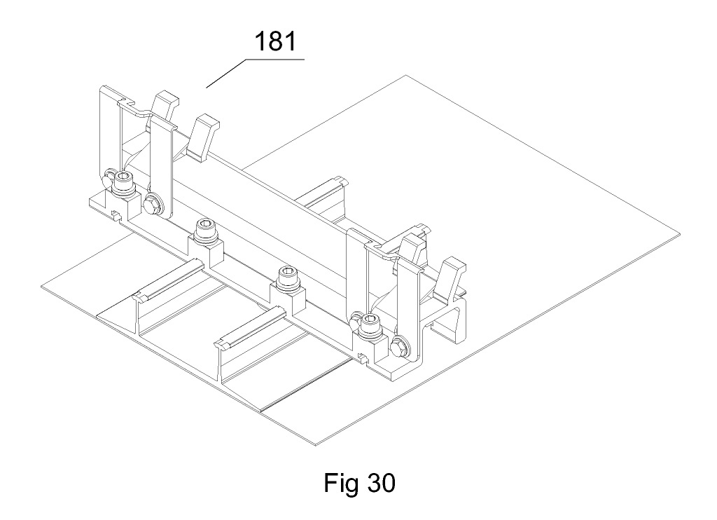

Embodiments of the present invention may include an audible engagement confirmation element when a solar panel module is completely engaged with a solar panel attachment system. When an end of a solar panel module moves into full engagement with an elastic solar panel coupling, a sound such as a click or the like may be created as at least part of at least one snap clip (164) snaps, perhaps even with a side flex, against the end of a solar panel module providing audible confirmation. As can be understood from FIGS. 10 and 13, an elastic top retainer (29) may flex as an end of a solar panel module is inserted into a coupling allowing the solar panel module to fully engage with the coupling. When engaged, an elastic top retainer may snap over the module. Thereafter, the elastic top retainer (29) may visually confirm engagement of the solar panel module to an attachment system in that the elastic top retainer can be seen placed over the solar panel module (32) thus providing a visual engagement confirmation element (165). In embodiments, an elastic top retainer may be a detachable elastic top retainer (26) which can be detachably attached to an attachment system. In another embodiment, the present invention may provide a multi-couplings clamp (181) such as shown in FIGS. 28 and 30. These various coupling embodiments may provide efficient assistance in the attachment of a solar panel module to an attachment system.

A rail mount may be used for new composition roofs and the like. Prior to the installation of the roofing, the rails may be secured to a roof sheathing. Typical roof sheathing may include OSB, plywood, diagonal sheathing, and the like. In an embodiment, a rail mount may be shaped to accept the composition roofing so that the roofing may form a water barrier for water penetration.

Specifically, embodiments of the present invention may provide a water deflection solar panel roof mount assembly system comprising a solar panel roof attachment rail having a bottom base, at least one vertical support attached to said solar panel roof attachment rail, a high ridge roofing positioner longitudinally located along a side of said bottom base of said solar panel roof attachment rail mount, wherein said high ridge roofing positioner runs parallel to said at least one vertical support, a laterally fluidically constrained channel configured from part of said bottom base of said solar panel roof attachment rail and part of said at least one vertical support, and a solar panel module responsive to said solar panel roof attachment rail. Methods of deflecting water through a solar panel roof mount assembly system to enhance a roof seal may comprise attaching a solar panel roof attachment rail having a longitudinal axis to a roof surface, vertically supporting a plurality of solar panel modules by said solar panel roof attachment rail, positioning a roof component over at least a portion of said solar panel roof attachment rail, ridging a portion of said roof component parallel to said longitudinal axis of said solar panel roof attachment rail through interaction between said roof component and said solar panel roof attachment rail, a laterally fluidically channeling any fluid permeating beyond said roof component in the vicinity of said solar panel roof attachment rail, and attaching said plurality of solar panel modules to said solar panel roof attachment rail.

As shown in FIGS. 2, 3, 4 and 7, a solar panel roof attachment rail (140) having a bottom base (141) and perhaps having a longitudinal axis may be used as one example of a rail mount for securement of solar panel modules to an area (162) such as a roof surface. At least one vertical support (4) of a solar panel roof attachment rail may be provided for vertically support of a solar panel module (32). Roof components (12), which may include but are not limited to shingles, tile shingles, rolled roofing, and the like, may be positioned over at least a portion of a solar panel roof attachment rail such as perhaps a high ridge roofing positioner (6) which may be longitudinally located along a side of a bottom base (141) and which may run parallel to at least one vertical support (4). A portion of a roof component (12) may be ridged parallel to a longitudinal axis of the solar panel roof attachment rail through interaction between the roof component and the solar panel roof attachment rail. In embodiments, a roofing insert (3) may be provided for insertion a roof component (12) into the solar panel roof attachment rail. A roof insert may include a gap between an end of a side lip (148) and an of a side ledge (150) of solar panel roof attachment rail. In embodiments, a roof insert may act as a raised ledge fluid diverter for diversion of fluids. A laterally fluidically constrained channel (5) may be configured from part of a bottom base (141) of a solar panel roof attachment rail and the vertical support (4) perhaps allowing laterally fluidically channeling of any fluid permeating beyond the roof component in the vicinity of the solar panel roof attachment rail. Of course, other embodiments of laterally fluidically channeling any fluid may be used such as but not limited to routing fluid through a groove, furrow, pathway, and the like. These embodiments may provide a watertight rail mount to which a plurality of solar module panels may be attached.

In embodiments and as shown as an extrudable cross section of a solar panel roof attachment rail (147) in FIG. 4, a solar panel roof attachment rail may include at least one vertical rail extension (142) perhaps from a vertical support, a side ridge elevator (143), and a concavity (144) below the side ridge elevator. Accordingly, in embodiments, a solar panel roof attachment rail may extensibly vertically support solar panel modules and may even side ridge elevate a roof component. As shown, this type of configuration of a solar panel roof attachment rail, once installed, can deflect and perhaps even channel fluids and water down a roof and thus prevent the fluids from leaking into and under a roof.

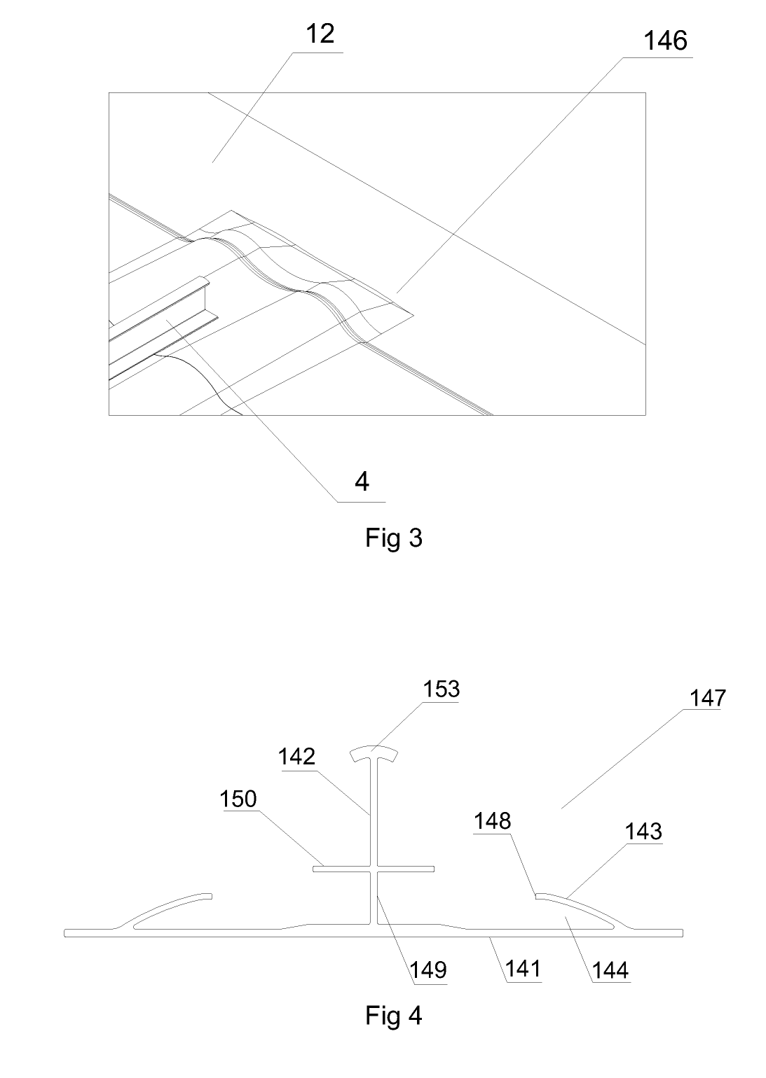

In embodiments, a system may provide a two sided open inner fluidically channeling of any fluid perhaps by providing two open inner channels oppositely adjacent to a vertical support (4). This may include a first side channel and a second side channel perhaps for first side fluidically channeling of a fluid and even for second side channeling of a fluid as may be understood from the channel (5) in FIG. 2. In embodiments, any number of channels may be provided. In other embodiments, a solar panel roof attachment rail may include an end fluid diverter (145) located at an end of a solar panel roof attachment rail for perhaps end fluid diverting of any fluids. An end fluid diverter (145) may include an end roofing diverter such as perhaps when a roofing component may used for end roof component diverting of fluid. An end fluid diverter (145) may act as a top diverter or perhaps even a bottom fluid diverter for fluid diverting of fluids. When a solar panel roof attachment rail, or even a plurality of connected solar roof attachment rails, are installed on a roof, there may be a top end and a bottom end. For example, a top end may be at a higher elevation and a bottom end may be at a lower elevation. A top end diverter (146) may include a roof material diverter perhaps by using roof material to assist in roof material diverting fluids from a roof and into or around the solar panel roof attachment rail and perhaps even to assist in sealing the rail from the fluids. As such, in embodiments, a rail oversurface diverter may be provided where a material (12), such as a roof material, shingle, or the like, may be placed over an end of a solar panel roof attachment rail as shown in FIG. 3 for perhaps rail oversurface diverting of fluids. A bottom diverter may include a roof material diverter perhaps by using roof material to assist in bottom fluid diverting fluids from and around a solar panel roof attachment rail and onto a roof material or other roofing components and perhaps even to assist in sealing the solar panel roof attachment rail from the fluids. As such, in embodiments, a rail undersurface diverter may be provided where a material, such as a roof material, shingle, or the like, may be placed under an end of a solar panel roof attachment rail as shown in FIG. 2 for perhaps rail undersurface diverting of fluids.

In embodiments, an extrudable cross section of a solar panel roof attachment rail (147) may include a base (141), a side lip (148), a vertical support (4) which may be located centrally to provide a central support (149), a top cross rail (153) and perhaps even a side ledge (150). A side ridge exterior mount surface (151) may be provided with perhaps screw holes (152) for fastening of the solar panel roof attachment rail to the surface with rail mount screws (7) as can be understood in FIGS. 2 and 10. Attached to a solar panel roof attachment rail may be a plurality of solar panel modules (32) as may be understood in FIGS. 23 and 24.

In embodiments, one type of roof mount may have an integrated flashing allowing for watertight roof penetration when attaching a solar panel support to an area. Specifically, embodiments of the present invention may provide a raised seal solar panel roof mount support assembly system comprising a solar panel roof mount bracket attached to a peripheral area surface element, wherein said peripheral area surface element is located below said solar panel roof mount bracket; at least one roof attachment placement hole in said solar panel roof mount bracket and said peripheral area surface element; a raised surface continuously integral with said peripheral area surface element adjacent to said roof attachment placement hole and located over a solar panel roof mount bracket hole edge; a roof mount bracket screw configured to fit in said roof attachment placement hole in said solar panel roof mount bracket and said peripheral area surface element; and an undercut bolt head cap of said roof mount bracket screw configured to fit over said raised surface located over said solar panel roof mount bracket hole edge. Methods may include connecting a solar panel roof mount bracket and a peripheral area surface element, each having at least one aligned attachment placement hole; establishing a raised surface continuously integral with said peripheral area surface element adjacent to said at least one aligned attachment placement hole; positioning said solar panel roof mount bracket on a roof; inserting a roof mount bracket screw configured to fit in said at least one aligned attachment placement hole in said solar panel roof mount bracket and said peripheral area surface element; cavitationally covering said raised surface continuously integral with said peripheral area surface element by an undercut bolt head cap of said roof mount bracket screw; and frictionally engaging at least a portion of said roof mount bracket screw with said connected solar panel roof mount bracket and said peripheral area surface element.

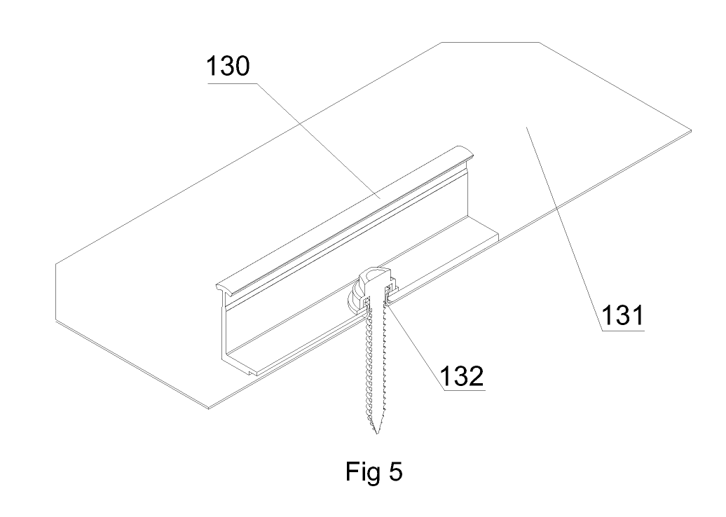

As shown in FIGS. 5, 6 and 34, embodiments of the present invention may include a solar panel roof bracket (130) attached to a peripheral area surface element (131) located below the solar panel roof mount bracket. A solar panel roof bracket (130) may include any type of roof mount used for mounting components to an area or a surface such as to a roof. This may include but is not limited to a rail mount, a roof mount, and the like. A peripheral area surface element may be a piece of sheet metal, flashing, covering and the like.

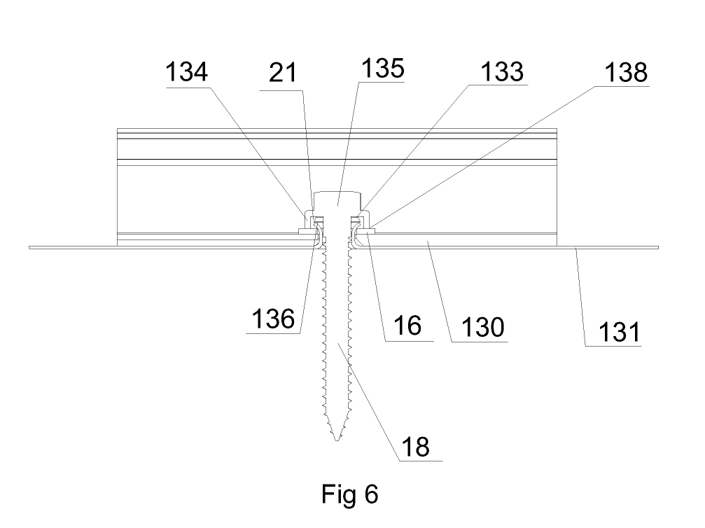

The present invention may provide in embodiments connecting a solar panel roof mount bracket and a peripheral area surface element, each having at least one aligned attachment placement hole (132) and perhaps even establishing a raised surface (136) continuously integral with a peripheral area surface element adjacent to at least one aligned attachment placement hole. A continuously integral raised surface with a peripheral area surface element may be a continuous attachment of a raised surface with a peripheral area surface element. A raised surface (136) may be located over a solar panel roof mount bracket hole edge as shown in FIG. 6. In embodiments a raised surface may be above, upon, connected, disconnected or the like with a solar panel roof mount bracket hole edge. This may be effective in creating a seal between the screw and the placement hole. Accordingly, a raised surface may act as a raised seal area around a solar panel roof mount bracket hole edge. Since a raised surface may be below a roof mount bracket screw, it may provide undersurface sealing of a solar panel roof mount bracket perhaps even with an undersurface seal. A raised surface (136) may radially extend perhaps over or around a solar panel roof mount bracket hole edge thus providing a radial extension seal.

Embodiments of the present invention may include forming an extensive perimeter surface perhaps for connection with a solar panel roof mount bracket. In embodiments a peripheral area surface element (131) may be an extensive perimeter surface. A perimeter surface may have a perimeter surface integral prominence which may be a projection, protuberance or the like perhaps even similar to a raised surface (136) as discussed herein. A perimeter surface may include a flat circular apex (133) which may be a tip, point, vortex, surface or the like perhaps between an engaged raised surface and a portion of a roof mount bracket screw as may be understood in FIG. 6. In other embodiments, a perimeter surface may be molded into a perimeter surface molding, may be deformed into a perimeter surface deformation, or perhaps may even be stretched into a stretched perimeter surface area. Any of these embodiments may be molded, deformed, stretched, or the like to form an integral prominence or the like as discussed herein in a perimeter surface. As one non-limiting example, a piece of flashing may be deformed and shaped to form a raised surface that can be continuously integral.

A roof mount bracket screw (18) may be configured to fit in a roof attachment placement hole (132) and may include an undercut bolt head cap (134) configured to fit over a raised surface (136) as shown in FIG. 6. In embodiments, an undercut bolt head cap (134) may include a driver head (135) and perhaps even an open area cap below said driver head. The configuration of this screw and the open area (21) therein may provide room to allow the cap to fit over a raised surface while retaining a sealing capability. In embodiments a driver head (135) may include an integral cap for utilization of an integral cap cover with the roof mount bracket. An undercut bolt head cap may be a circular shaped cap. Further, in embodiments, an outer bottom edge (138) of an undercut bolt head cap (134) may provide an integral radial extension and perhaps even an open space (21) may provide an integral axial spacer. In embodiments, an O-ring washer (16) or even O-ring sealing may be provided and may even be placed in between a roof mount bracket screw and a solar panel roof mount bracket as shown in FIG. 6. Alternatively, a molded elastomer may be placed in between a roof mount bracket screw and a solar panel roof mount bracket. In embodiments, a deformable inner concavity washer may be deformed perhaps when a roof mount bracket screw engages with a solar panel roof mount bracket.

When attaching a solar panel roof mount bracket to a roof, one may position a solar panel roof mount bracket on a roof, insert a roof mount bracket screw (18) in at least one aligned attachment placement hole, cavitationally cover a raised surface by an undercut bolt head of the roof mount bracket screw, and perhaps even frictionally engage at least a portion of a roof mount bracket screw with a connected solar panel roof mount bracket and peripheral area surface element. Frictional engagement may be created by head driving at least a portion of a screw. Cavitationally covering a raised surface may create an open area below an undercut bolt head cap (21). A cavitational covering may include a covering of a cavity and is not meant to include any fluidics formation in a cavitation. Frictional engagement may be created between an outer bottom edge (138) of an undercut bolt head cap and a solar panel roof mount bracket (130). Alternatively, frictional engagement may be created between an outer bottom edge (138) of an undercut bolt head cap and a washer (16).

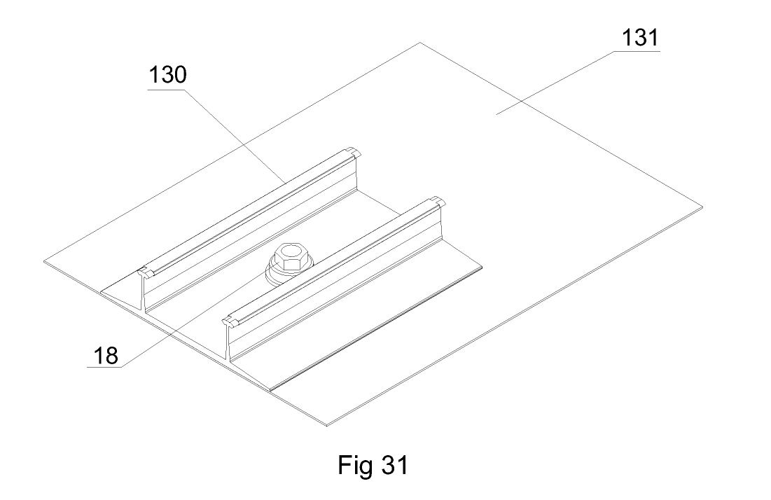

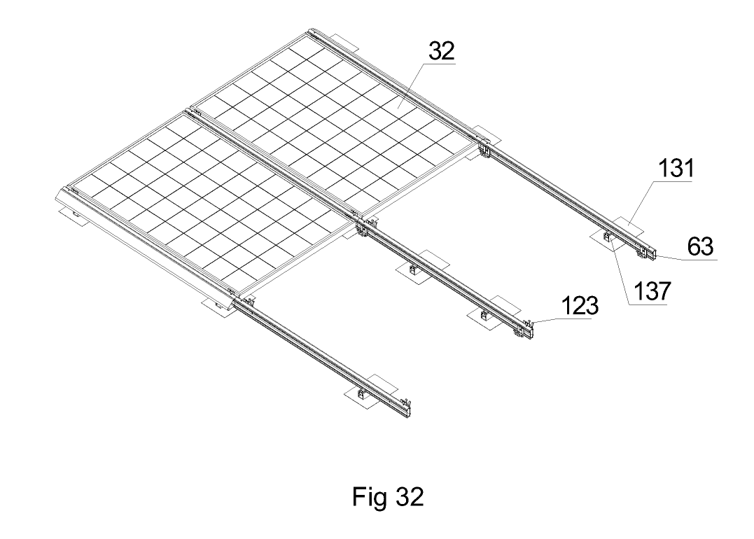

In embodiments, a roof mount perhaps even a solar panel roof mount bracket may include a slide element (137) for attachment of solar panel modules to the bracket perhaps with clamps, couplings, railings, and the like. A slide element may be a truncated rail. Thus, the present invention may provide sliding of a mount element and perhaps even sliding a truncated rail in various embodiments. As can be understood from FIGS. 5 and 6 a raised surface embodiment with a solar panel roof mount bracket hole may provide an intra-channel attaching a solar panel roof mount bracket to a roof perhaps with an intra-channel attachment element such as shown by a roof mount bracket screw (18) located in between two rail channels as shown in FIG. 31.

In a broad embodiment, an attachment system may comprise a screw; an undercut bolt head cap of said screw; a peripheral area surface element underneath said undercut bolt head cap of said screw; and a raised surface continuously integral with said peripheral area surface element.

Roof clamps and rail mounts may not have to be accurately located since module clamps may move on a module and the mounts perhaps covering two directions. This flexibility may allow roofers to easily install roof mounts and may also provide a better probability for leakproof roofs. In most mounting systems, a PV installer may be the one who installs the mounts and they may void the roof warranties. Thus, if a roofer can install the roof mounts or rail mounts, this may not void any warranties.

In embodiments, the present invention may provide a plurality of suspended substantially rigid hollow rail components; at least one attachment hole in said suspended substantially rigid hollow rail components; a plurality of interior continuous rail splice connectors having frictionally matable ends; an integral clamp attachment channel located on a side of said suspended substantially rigid hollow rail components; a pair of integral angled mount attachment feet located at a bottom of said suspended substantially rigid hollow rail components; a plurality of continuously adjustable roof mount supports securely responsive to said integral angled mount attachment feet of said suspended substantially rigid hollow rail components; a plurality of solar panel attachment components responsive to said integral clamp attachment channel of said suspended substantially rigid hollow rail components; and an array of solar panel modules responsive to said plurality of said solar panel attachment components. Methods may include connecting a plurality of continuously adjustable roof mount supports to a mount surface; establishing at least two substantially rigid hollow rail components for a mount surface; interiorly inserting at least one interior continuous rail splice connector into said at least two substantially rigid hollow rail components; engaging an interior surface of both of said at least two substantially rigid hollow rail components by said at least one interior continuous rail splice connector; suspending said at least two substantially rigid hollow rail components above said mount surface by a pair of integral angled mount attachment feet located at a bottom of said suspended substantially rigid hollow rail components; providing an integral clamp attachment channel located on a side of said suspended substantially rigid hollow rail components; clamping said pair of integral angled mount attachment feet to at least one of said plurality of continuously adjustable roof mount supports; directionally transforming clamping forces by interaction between said pair of integral angled mount attachment feet and said continuously adjustable roof mount supports; creating a downward attachment force between at least one of said substantially rigid hollow rail components and at least one of said continuously adjustable roof mount supports by action of said step of directionally transforming clamping forces by interaction between said pair of integral angled mount attachment feet and said continuously adjustable roof mount supports; creating a mount fixation force for at least one of said continuously adjustable roof mount supports by action of said step of directionally transforming clamping forces by interaction between said pair of integral angled mount attachment feet and said continuously adjustable roof mount supports; fastening a plurality of solar panel attachment components to said at least two substantially rigid hollow rail components; and attaching an array of solar panel modules to said plurality of said solar panel attachment components.

In alternative embodiments, the present invention may provide a rail mount solar power installment system comprising: a plurality of suspended substantially rigid hollow rail components; an integral clamp attachment channel located on a side of said suspended substantially rigid hollow rail components; a pair of integral angled mount attachment feet located at a bottom of said suspended substantially rigid hollow rail components; a plurality of continuously adjustable roof mount supports securely responsive to said integral angled mount attachment feet of said suspended substantially rigid hollow rail components; a plurality of solar panel attachment components responsive to said integral clamp attachment channel of said suspended substantially rigid hollow rail components; and an array of solar panel modules responsive to said plurality of said solar panel attachment components.

Further, the present invention may provide a method of rail mounting a solar power system comprising the steps of: connecting a plurality of continuously adjustable roof mount supports to a mount surface; establishing at least one substantially rigid hollow rail components for said mount surface; suspending said at least two substantially rigid hollow rail components above said mount surface by a pair of integral angled mount attachment feet located at a bottom of said suspended substantially rigid hollow rail components; providing an integral clamp attachment channel located on a side of said suspended substantially rigid hollow rail components; clamping said pair of integral angled mount attachment feet to at least one of said plurality of continuously adjustable roof mount supports; directionally transforming clamping forces by interaction between said pair of integral angled mount attachment feet and said continuously adjustable roof mount supports; creating a downward attachment force between at least one of said substantially rigid hollow rail components and at least one of said continuously adjustable roof mount supports by action of said step of directionally transforming clamping forces by interaction between said pair of integral angled mount attachment feet and said continuously adjustable roof mount supports; creating a mount fixation force for at least one of said continuously adjustable roof mount supports by action of said step of directionally transforming clamping forces by interaction between said pair of integral angled mount attachment feet and said continuously adjustable roof mount supports; fastening a plurality of solar panel attachment components to said at least two substantially rigid hollow rail components; and attaching an array of solar panel modules to said plurality of said solar panel attachment components.

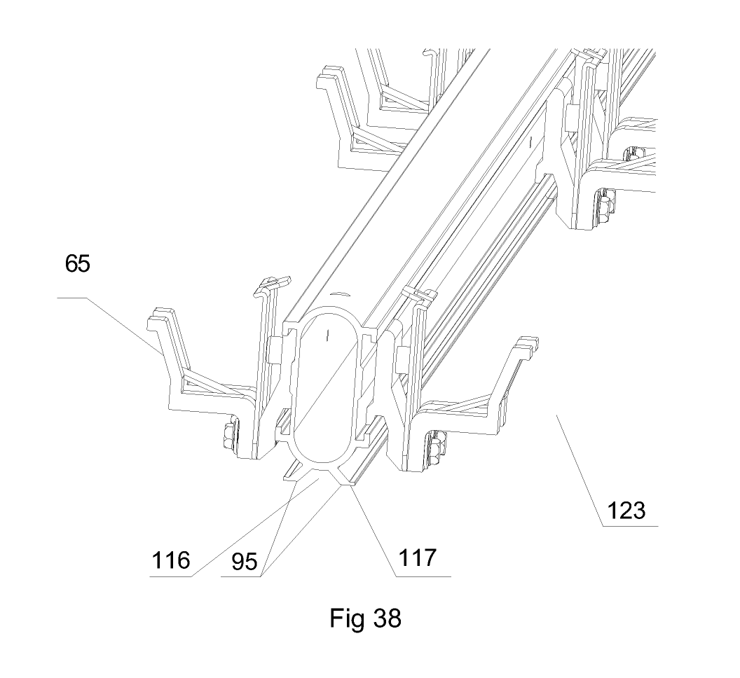

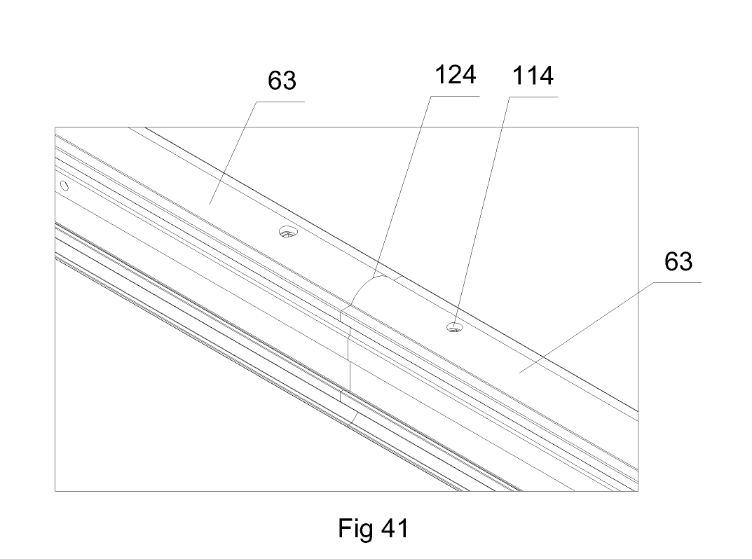

A rail mount solar panel installment system may include, in embodiments, suspended substantially rigid hollow rail components (63) perhaps with at least one attachment hole (114) as may be provided in various embodiments and as shown in FIGS. 33 and 41. Integral clamp attachment channels (110) may be located on the sides of the suspended substantially rigid hollow rail components and may even include two opposing integral clamp attachment channels located on each side of the suspended substantially rigid hollow rail components for perhaps opposed clamping capabilities. An integral clamp attachment channel may be any type of configuration which allows clamp attachment to the suspended substantially rigid hollow rail components. Substantially rigid hollow rail components may be suspended above a mount surface by a pair of integral angled mount attachment feet (95) which may be located at a bottom of the suspended substantially rigid hollow rail components. In embodiments, integral mount attachment feet (95) may be extrusion compatible feet perhaps to engage with a mount support. Integral mount attachment feet (95) may include a ramp foot portion (116) and a rail congruent foot portion (117) as shown in FIG. 38. A ramp foot portion (116) of integral mount attachment feet may provide paired center up ramps which may provide an incline on the integral mount attachment feet. A rail congruent foot portion (117) of integral mount attachment feet (95) may include a flat surface friction portion perhaps where the feet may frictionally engage with a mount.

A plurality of continuously adjustable roof mount supports (118) may be securely responsive to the integral angled mount attachment feet. In embodiments, a continuously adjustable roof mount support may securely connect to integral angled mount attachment feet and may even be connected to an area, a mount surface, and the like. In an embodiment, a pair of integral angled mount attachment feet may be clamped to at least one of a plurality of continuously adjustable roof mount supports. A plurality of solar panel attachment components (123) fastened to substantially rigid hollow rail components and may even be responsive to an integral clamp attachment channel (110) of a suspended substantially rigid hollow rail component. In embodiments, solar panel attachment components may include any type of clamp, coupling, movable clamp, flexible clamp, slidable clamp, and the like with may connect to an integral clamp attachment channel of a suspended substantially rigid hollow rail component. An array of solar panel modules (32) may be responsive to the solar panel attachment components in that the modules may fasten, connect, attach, clip, clamp, engage, and the like with the solar panel attachment components.

In embodiments, the present invention may provide directionally transforming clamping forces by interaction between a pair of angled mount attachment feet and a continuously adjustable roof mount supports. In embodiments the present invention may create downward attachment force between at least one of a substantially rigid hollow rail components and at least one of a continuously adjustable roof mount supports by action of directionally transforming clamping forces by interaction between a pair of integral angled mount attachment feet and the continuously adjustable roof mount supports. In embodiments the present invention may create mount fixation force for at least one of a continuously adjustable roof mount supports by action of directionally transforming clamping forces by interaction between a pair of integral angled mount attachment feet and a continuously adjustable roof mount supports.

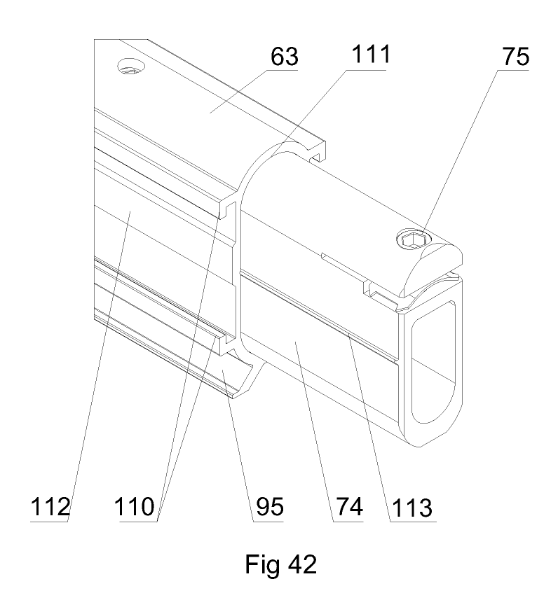

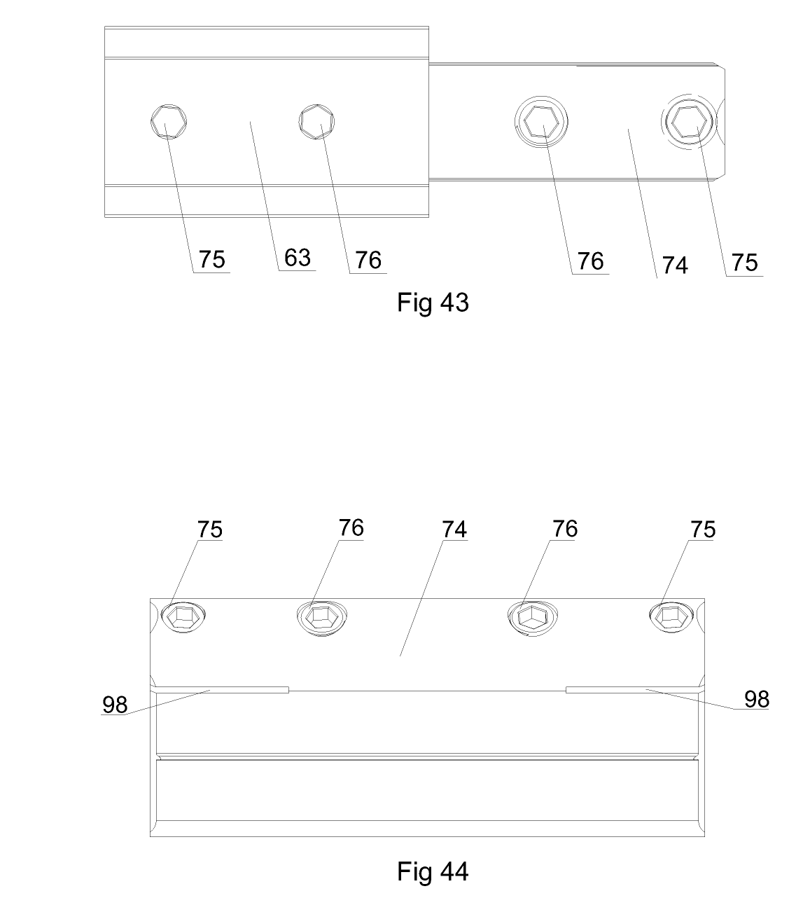

Suspended substantially rigid hollow rail components (63) may be spliced together with a plurality of interior continuous rail splice connectors (74) perhaps having frictionally matable ends such as when an interior surface of both the substantially rigid hollow rail components and interior continuous rail splice connector are engaged such as shown in FIGS. 42, 43, and 44. Accordingly, an interior continuous rail splice connector may have ends which may frictionally mate with ends of suspended substantially rigid hollow rail components when they may be interiorly inserted into at least two substantially rigid hollow rail components. In embodiments, a plurality of interior continuous rail splice connectors (74) may include at least two splice slots (98). In embodiments, the present invention may provide continuous abutment (124) between one end of a first suspended substantially rigid hollow rail component and one end of a second suspended substantially rigid hollow rail component when two suspended substantially rigid hollow rail components are placed together with one of said interior continuous rail splice connectors such as shown in FIG. 30. A continuous abutment may include a smooth connection between two substantially rigid hollow rail components. Alternatively, embodiments of the present invention may provide a system with a suspended substantially rigid hollow rail component without the need for an interior continuous rail splice connector.

In embodiments, rail splice grounding fasteners such as an electrical fastener (76) can be used in place of rail splice fasteners such as a mechanical fastener. Multiple electrical fasteners can be used for each rail. If only electrical fasteners or a combination of electrical and mechanical fasteners are used to jam into the top inside surface of a rail, then the rail splice slots (98) may not be needed.

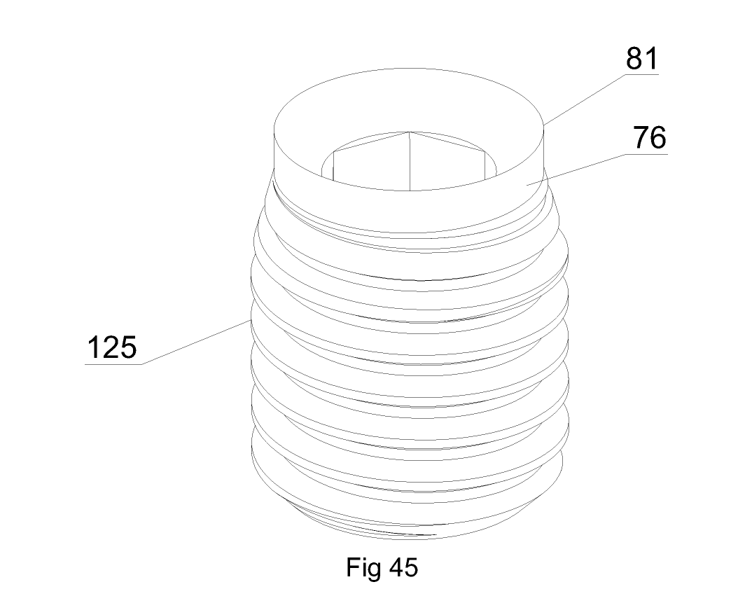

Roof clamps, rail mounts, and any component of a solar panel attachment system may need to be fastened to each other, to a surface, and the like and may be achieved by providing fasteners. As mentioned above, fasteners (75) may include any of various devices for fastening including but not limited to screws, clips, snaps, bolts, clasps, tightening fasteners, locks, latches, rivets, holders, and the like. In an embodiment, the present invention may provide activating a fastener connected to a substantially rigid hollow rail component. In another embodiment, splice fasteners may be used to connect an interior continuous rail splice connector to a substantially rigid hollow rail component. Embodiments may include tightening a fastener connected to a substantially rigid hollow rail component perhaps with an increased surface friction fastener (125) as shown in FIG. 45. An increased surface friction fastener (125) may provide greater surface resistance between the fastener and the engaging surface. This action may result in a splice deformable fastener which may deform at least one interior continuous rail splice connector when engaged with the fastener. An example of a deformation to a rail splice connector may include an expansion of at least one interior continuous rail splice connector perhaps even providing a splice expansion fastener. In embodiments, an increased surface friction fastener (125) may include a surface impingement fastener which may impinge a surface of substantially rigid hollow rail component perhaps by impacting or colliding with the substantially rigid hollow rail component. A fastener may include in embodiments, an impingement electrical contact fastener where a fastener may provide an electrical connection with a surface. This may be achieved in one embodiment by a sharp lip fastener having a sharp lip (81) as shown in FIG. 45. In other embodiments, a fastener may be an inner surface integral fastener, a splice contained fastener, and a rail attachment hole coordinated fastener.

In embodiments, fasteners (75) may include but are not limited to a combined mechanical fastener and electrical fastener, an electrical fastener, a mechanical fastener, an up fastener, a down fastener, a forward thread fastener, a reverse thread fastener, combinations thereof and the like. Fasteners (75) may be paired fasteners in embodiments perhaps for paired fastening to the substantially rigid hollow rail component. Paired fasteners may include an up fastener, a down fastener, and may even include a mechanical fastener (75) and an electrical fastener (76). Mechanical fastening may include a forward thread fastener and perhaps electrical fastening may include a reverse thread fastener. In embodiments, a mechanical fastener may include an outer splice fastener and perhaps even an electrical fastener may include an inner splice fastener. Fasteners may be used with our without rail splice slots.

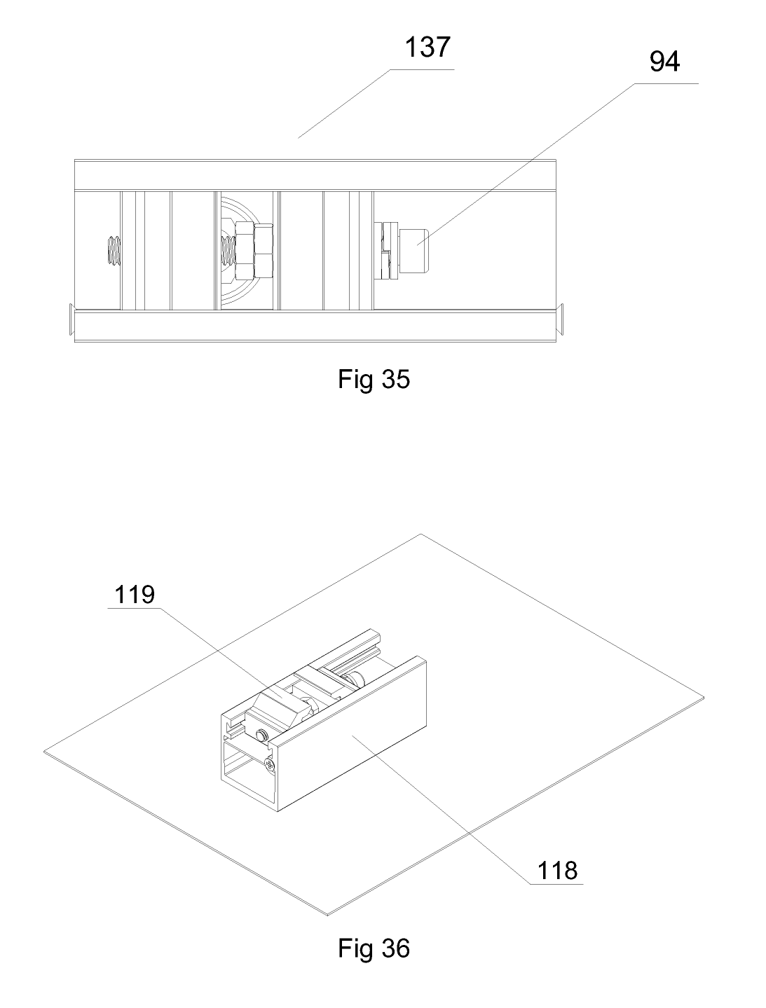

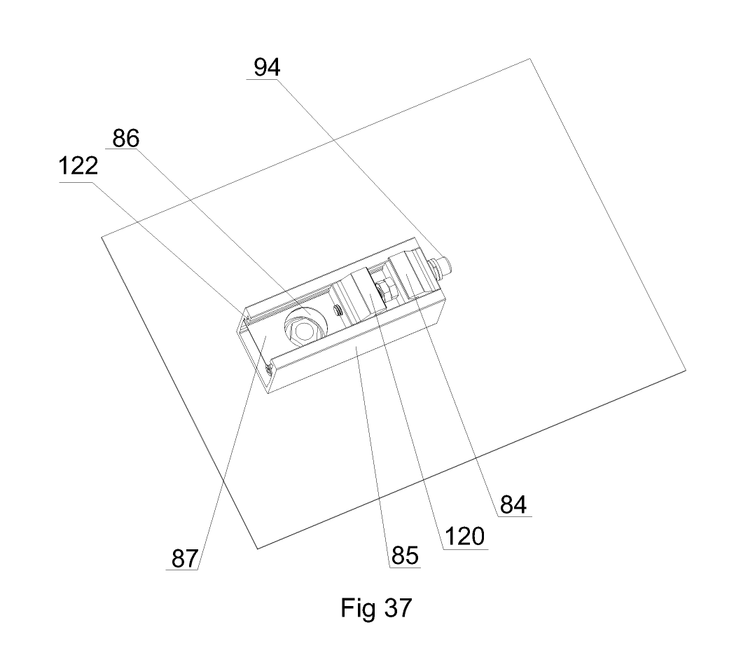

Continuously adjustable roof mount supports (118) may include a position adjustable support such as shown in FIGS. 35-37 so that perhaps substantially rigid hollow rail components may be position adjustable when attached to the position adjustable support. For example, FIG. 36 shows an adjustable roof mount support in a first position (119) and FIG. 37 shows an adjustable roof mount support in a second position (120). In embodiments, a position adjustable support may be an orthogonally adjustable support providing orthogonally adjustable movement and perhaps even a continuous adjustable support providing continuous adjustability of an attached component. As shown in FIG. 36, this type of adjustable roof mount support (118) may be a truncated rail support providing truncated rail suspension of perhaps substantially rigid hollow rail components or the like. Further, an adjustable roof mount support (118) may include a slidable rail support perhaps providing slidable rail suspending of substantially rigid hollow rail components or the like. In embodiments, an adjustable roof mount support (118) may provide single point fixably fastening of a component with a single point fixable support and may even include single tightening of a component with a single tightener support. This may include a fastening of the adjustable roof mount support at a single point with perhaps a rail clamp fastener (94) acting as a single tightener which in embodiments, may include but is not limited to a single point adjustment fastener such as a screw.

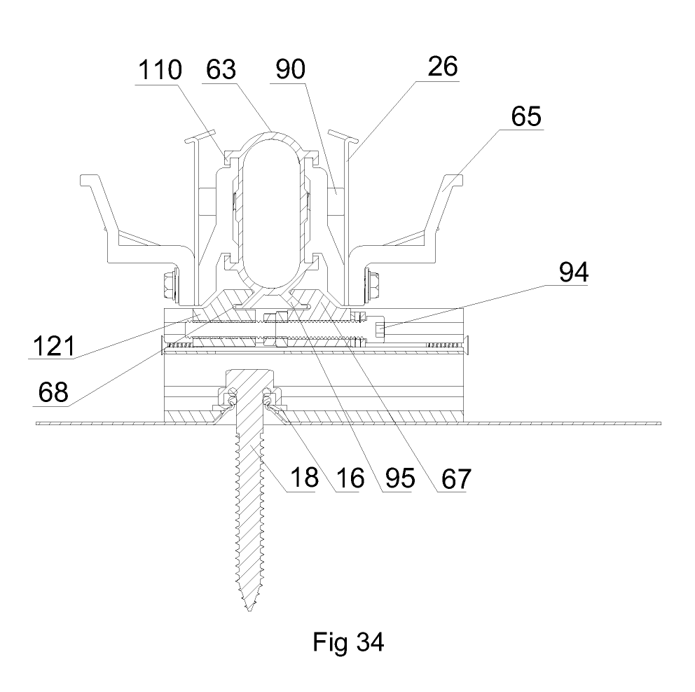

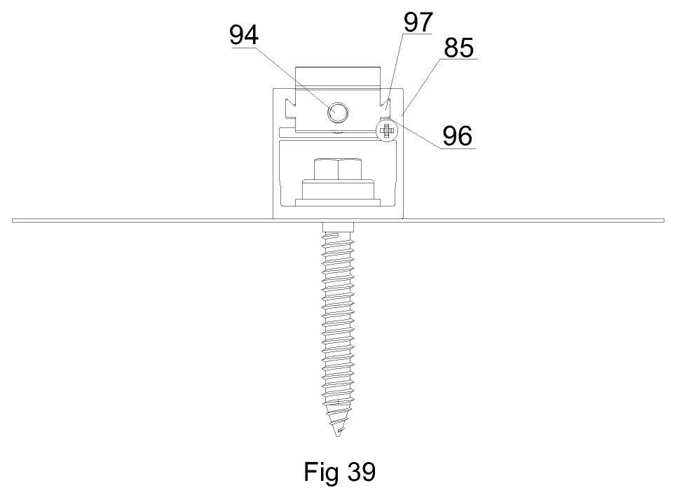

In embodiments, continuously adjustable roof mount supports may include a clamp support (121) to perhaps provide clamping of a substantially rigid hollow rail component as understood in FIGS. 34, 37, and 39. A suspended substantially rigid hollow rail component (63) may be secured to a roof mount bracket (85) perhaps by a clamped support (121). A clamped support (121) may include two clamp elements (67) which may be responsive to a rail clamp fastener (94) and may move to tighten against integrally formed feet (95) of a substantially rigid hollow rail component (63). When this occurs, the bottom of the clamp elements (67) may force the integrally formed feet against the top of the top of the roof mount bracket (85) perhaps by the slanted surfaces of the clamp elements (67). The clamp elements (67) may be prevented from moving upward by a foot surface engagement retainer (97) and a roof mount bracket groove (96) as shown in FIG. 39. A slanted surface of a foot surface engagement retainer (97) and the roof mount bracket groove (96) may force the clamp elements (67) to tighten the clamp elements against the roof mount bracket (85). The tightening of a rail clamp fastener (94) may securely bind the substantially rigid hollow rail component (63), the clamp elements (67), and perhaps even the roof mount bracket (85) tightly together.

Accordingly, a clamp element (67) may include an angled clamp element which may provide angled clamping to a pair of integral angled mount attachment feet of a substantially rigid hollow rail component. In embodiments, an angled clamp mount (67) may include paired angled feet synchronized clamping of integral angled mount attachment feet of a substantially rigid hollow rail component with paired angled feet synchronized clamp elements (68). This may provide a clamp element having synchronous clamping to each of the integral angled mount attachment feet. Paired angled feet synchronized clamp elements (68) may also function as downforce clamp elements perhaps providing downward clamping onto the integral angled mount attachment feet. In embodiments, a clamp support (121) may function as an off axis retainer perhaps providing off-axis retaining of the integral angled mount attachment feet of the suspended substantially rigid hollow rail components. For example, a clamp support (121) may clamp along an axis which may be different from a retainment axis thus providing an angular bottom force which may be off-axis from a clamp force. In embodiments adjustable roof mount support (118) may include but is not limited to a friction establishment retainer perhaps providing frictional retainment, a slide channel engagement retainer (122) perhaps providing engagement with a slide channel, and perhaps even a foot surface engagement retainer (97) perhaps providing engagement with a foot surface of a clamp support (121).

The present invention may provide, in embodiments, a plurality of suspended substantially rigid hollow rail components (63) may have an oval cross section element as shown in FIG. 34. The suspended substantially rigid hollow rail components (63) may have integrally formed feet (95) with may be angled or may not be angled. Integrally formed feet (95) may form integrally formed opposed attachment channels perhaps to provide attachment to a mount component. Suspended substantially rigid hollow rail components (63) may include an integrally formed smooth top (111) as shown in FIG. 42 which may be connected perhaps with a hollow coordinated interior continuous rail splice connectors (74). In embodiments, a splice may be an oval splice and may even include an integrally formed suspension slide (113), and perhaps even an integrally formed opposed side bosses (112). When a hollow coordinated interior continuous rail splice connector may be inserted into a substantially rigid hollow rail component, the integrally formed suspension slide may engage with the substantially rigid hollow rail component and perhaps even the integrally formed opposed side bosses may be connected.

Electrical connection of the modules may be made through connectors integrated within the frame. Grounding between the modules and the electrical connection may occur when the modules are locked together. In embodiments, an electrical connection and grounding of the solar panel modules can be done manually per typical standard practices in the solar panel installations.

Therefore, embodiments of the present invention may provide an electrically grounded solar panel mount system comprising a solar panel module; at least one solar panel roof mount constraint; a solar panel electrical penetration connector on said at least one solar panel roof mount constraint; and a solar panel module pivot element configured to pierce said solar panel electrical penetration connector into said solar panel module. Methods may include connecting at least one solar panel roof mount constraint to a roof; engaging at least a first end of a solar panel module to said at least one solar panel roof mount constraint; pivoting said solar panel module while engaged with said at least one solar panel roof mount constraint; deformably penetrating at least a portion of said solar panel module by at least a portion of said at least one solar panel roof mount constraint through action of said step of pivoting said solar panel module while engaged with said at least one solar panel roof mount constraint; and unequivocally electrically connecting said solar panel module and said at least one solar panel roof mount constraint through said step of deformably penetrating at least a portion of said solar panel module.

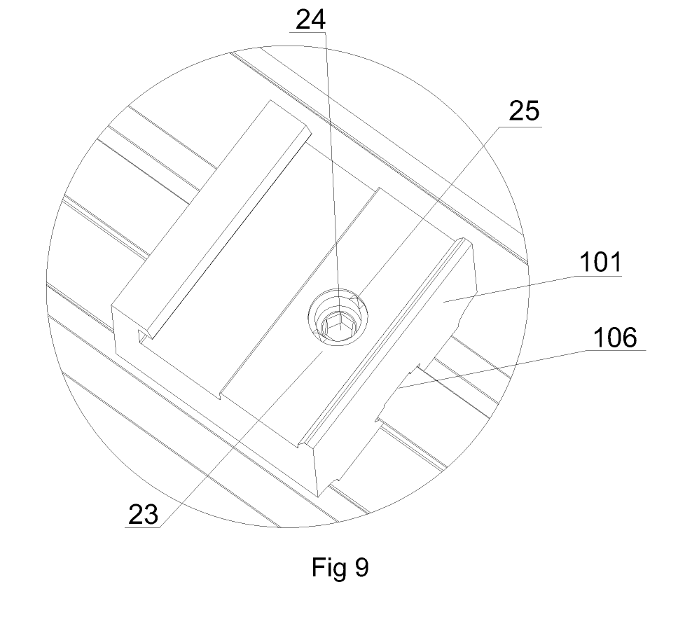

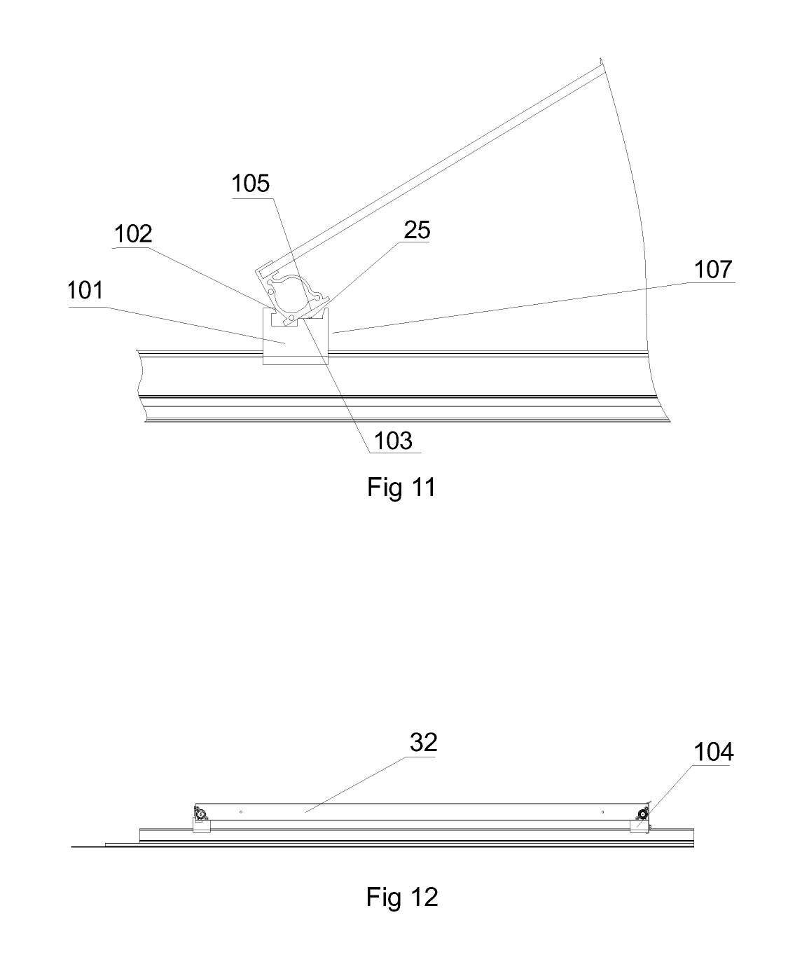

In embodiments, a solar panel electrical penetration connector (25) may be located on a solar panel roof mount constraint (101). As discussed herein, a solar panel roof mount constraint may be any type of clamp, coupling, attachment and the like which may be provided to mount a solar panel module (32) to a surface. A solar panel module pivot element (107) may be provided and may be configured to pierce a solar panel electrical penetration connection into a solar panel module. In embodiments, a pivot element (107) may include a fulcrum force multiplier to perhaps provide fulcrum force multiplication to a solar panel module. A solar panel electrical penetration connector (25) may be a pierce insert (23) perhaps projecting from a solar panel roof mount constraint perhaps causing surface piercing of at least part of a solar panel module. A pierce insert (23) may be connected to a rail mount (106). A solar panel electrical penetration connector (25) may be a concentric bolt element (24) with piercing capability and may even be a rail fastener in embodiments as shown in FIG. 9. A solar panel electrical penetration connector (25) may include a pivot lip (102) and perhaps even a pivot limit surface (103) as shown in FIG. 11.

In embodiments, a solar panel electrical penetration connector (25) may be a tooth projecting from a solar panel roof mount constraint perhaps causing tooth penetration of at least part of a solar panel module. This tooth may be a sharp tooth perhaps causing sharp tooth penetration of at least part of a solar panel module and a tooth may have a second hardness greater than a first hardness (105) of a solar panel module surface. In other embodiments, a solar panel module may be made of a softer material than a tooth material but a solar panel module may have a thin layer of hard material making it harder than a tooth surface. However, a force of a pivot of a solar panel module may cause the tooth to break through the thin layer. For example, a solar panel module may be made of aluminum anodized with a thin layer of material that is harder than the tooth.

When installing a system, the present invention may provide, in embodiments, connecting at least one solar panel roof mount constraint (101) to a roof. At least a first end of a solar panel module (32) may be engaged with at least one solar panel roof mount constraint (101), such as shown in FIG. 11. The solar panel module may be pivoted while engaged with at least one solar panel roof mount constraint, perhaps even with a pivot element (107). At least a portion of a solar panel module, such as but not limited to a solar panel frame, may be deformably penetrated by at least a portion of a solar panel roof constraint through the pivoting action and perhaps even a solar panel module may be unequivocally electrically connected to at least one solar panel roof mount constraint through the deformably penetration action. This may occur when the solar panel electrical penetration connector pierces into the solar panel module.

In embodiments, a solar panel electrical penetration connector (25) may include a spaced edge attachment element (104) as shown in FIG. 12. This may provide a solar panel spaced apart from at least one solar panel roof mount constraint. Therefore, a spaced edge of a solar panel module may be attached perhaps even elastically attached to at least one solar panel roof mount constraint.

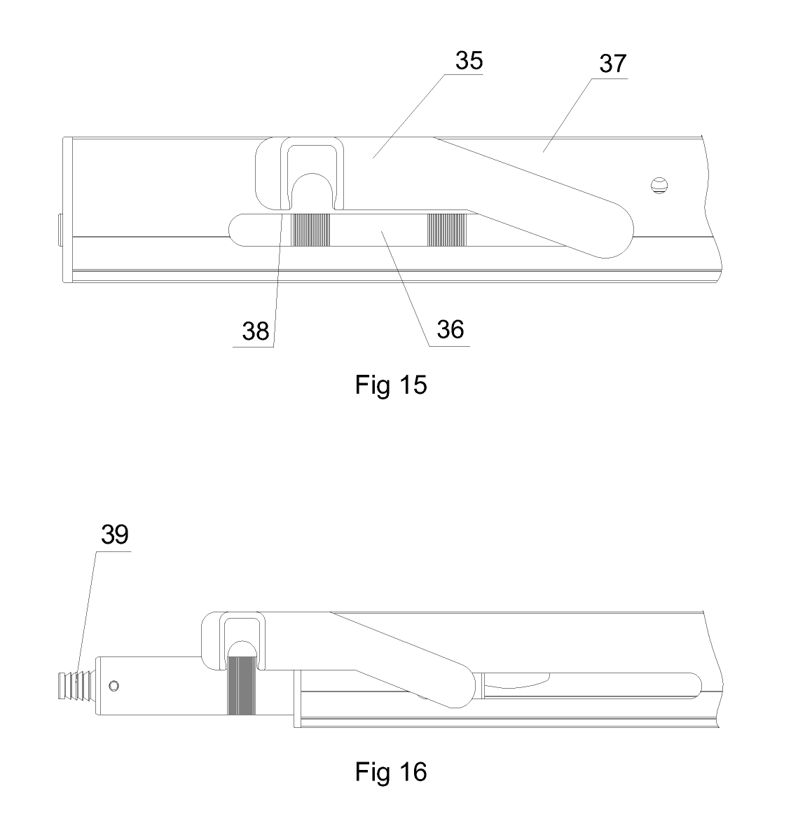

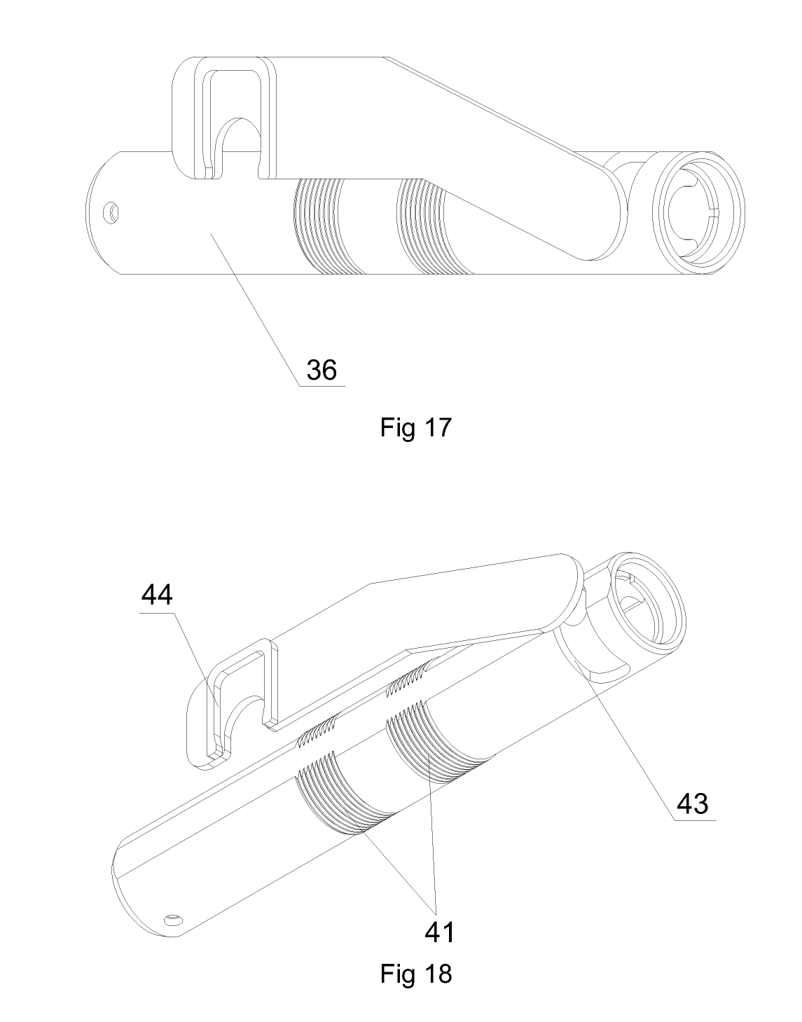

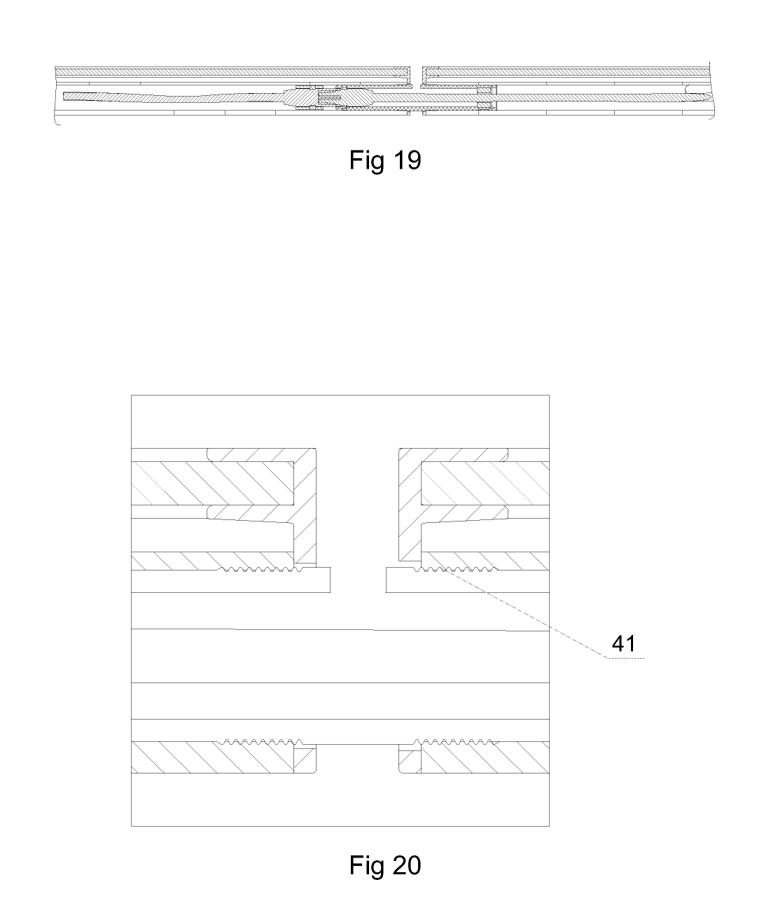

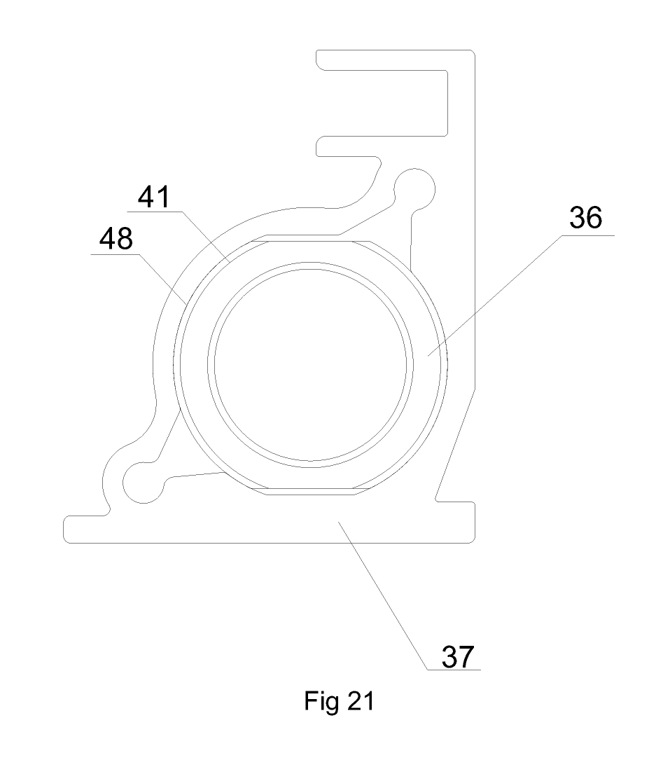

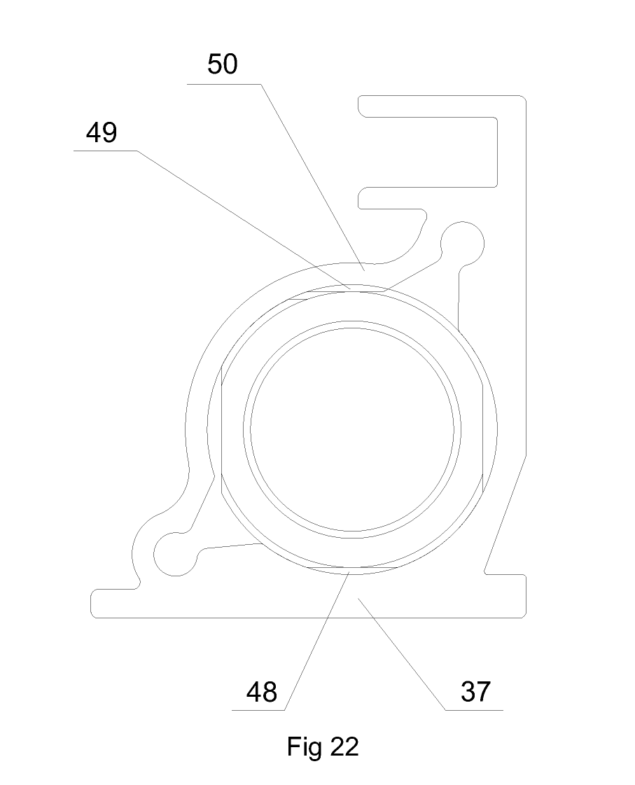

As mentioned earlier, the solar panel modules can be locked together once put into place. FIGS. 15-27 provide embodiments of a locking system. FIG. 15 shows an embodiment of the invention providing a spar (36) which can be seen through a frame slot (38) in the frame (37). A latch (35) can move a spar (36) in the frame (37). The spar can move easily in the frame. In FIG. 16, the spar has been pulled out to the extended position. Now the connector (39) can be seen in the spar. This may be how the electrical connections are made between the modules. In FIG. 17, the latch stud may be threaded into a c-ring. The c-ring can be rotated in the spar (36) within the spar slot (43). The c-ring may be held in place by the retaining ring. FIG. 18 shows the spar rotated 90 degrees. Note the slot location and spar thread (41). This may be an important feature because this may lock the modules together. A latch snap ring (44) is shown and may prevent the latch from unlatching. FIG. 19 shows a 2-D cross section of the spar and frame. FIG. 20 is a close-up of FIG. 19. The spar threads can be seen here. FIG. 21 shows a cross section of a spar (36) and long frame (37) with a spar rotated in the position that it can be moved with the frame. Note the clearance (48) between the spar thread (41) and the long frame (37). FIG. 22 shows a cross section with a spar rotated 90 degree. Note that there is no clearance (48) between the spar and frame outside the thread and thread forming (49). This may occur at the top and bottom of the spar. The long frame (37) may be designed to flex slightly (50) when the threads are formed so that there is a gas tight contact between the spar and long frame. This may allow the spar to be locked and unlocked many times without loss of ground after locking again.

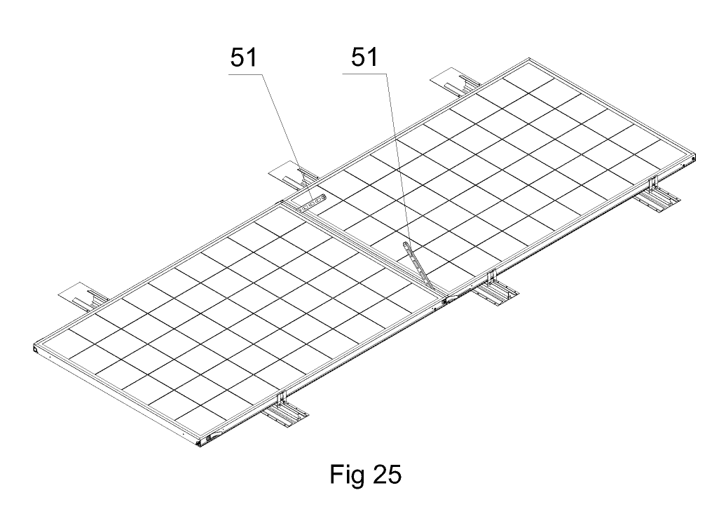

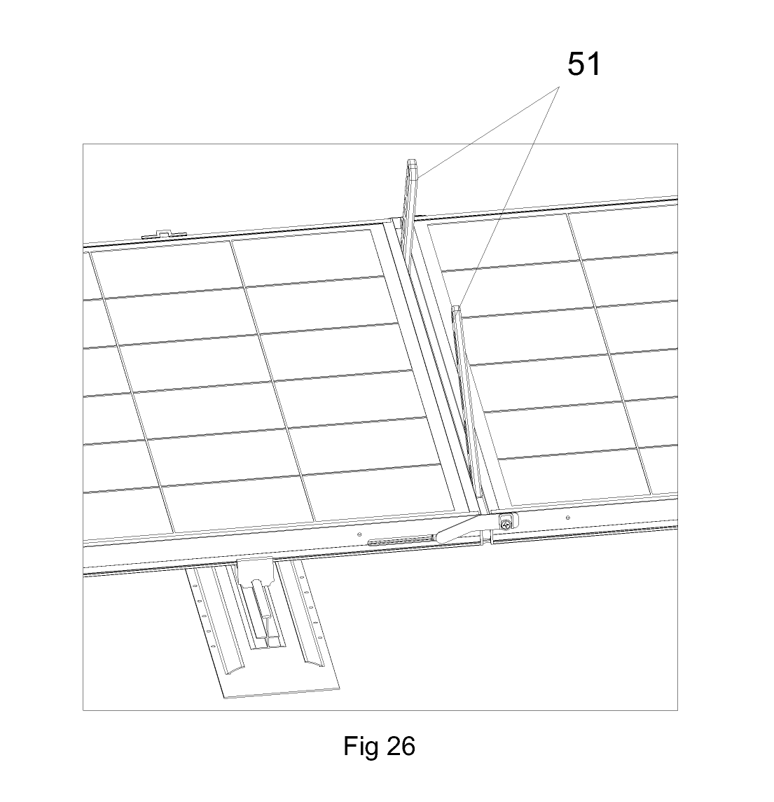

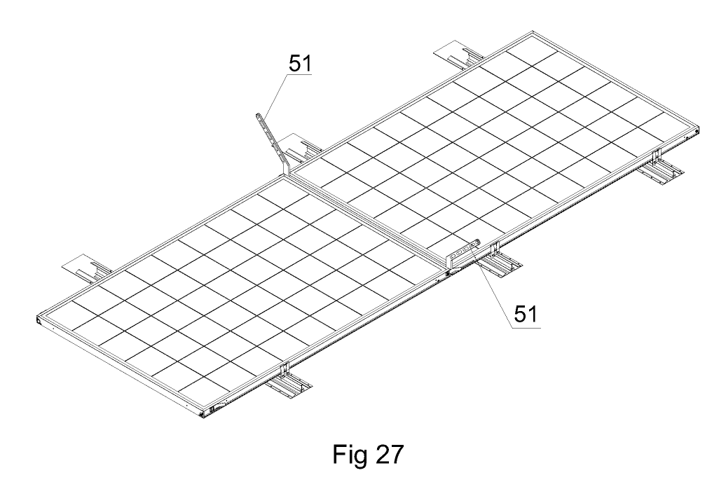

FIGS. 23 and 24 shows an embodiment of a solar panel module attached to a rail mount system. In FIG. 25, the spar tools are in place to turn the spar. The spar tools (51) are also used to set the space between the modules. FIG. 26 shows that a rear latch may be latched properly. FIG. 27 shows the spar tools (51) after rotation of the spar.

As can be easily understood from the foregoing, the basic concepts of the present invention may be embodied in a variety of ways. It involves both solar panel installation techniques as well as devices to accomplish the appropriate solar panel installation system. In this application, the solar pane installation techniques are disclosed as part of the results shown to be achieved by the various devices described and as steps which are inherent to utilization. They are simply the natural result of utilizing the devices as intended and described. In addition, while some devices are disclosed, it should be understood that these not only accomplish certain methods but also can be varied in a number of ways. Importantly, as to all of the foregoing, all of these facets should be understood to be encompassed by this disclosure.

The discussion included in this application is intended to serve as a basic description. The reader should be aware that the specific discussion may not explicitly describe all embodiments possible; many alternatives are implicit. It also may not fully explain the generic nature of the invention and may not explicitly show how each feature or element can actually be representative of a broader function or of a great variety of alternative or equivalent elements. Again, these are implicitly included in this disclosure. Where the invention is described in device-oriented terminology, each element of the device implicitly performs a function. Apparatus claims may not only be included for the device described, but also method or process claims may be included to address the functions the invention and each element performs. Neither the description nor the terminology is intended to limit the scope of the claims that will be included in any subsequent patent application.

It should also be understood that a variety of changes may be made without departing from the essence of the invention. Such changes are also implicitly included in the description. They still fall within the scope of this invention. A broad disclosure encompassing both the explicit embodiment(s) shown, the great variety of implicit alternative embodiments, and the broad methods or processes and the like are encompassed by this disclosure and may be relied upon when drafting the claims for any subsequent patent application. It should be understood that such language changes and broader or more detailed claiming may be accomplished at a later date (such as by any required deadline) or in the event the applicant subsequently seeks a patent filing based on this filing. With this understanding, the reader should be aware that this disclosure is to be understood to support any subsequently filed patent application that may seek examination of as broad a base of claims as deemed within the applicant's right and may be designed to yield a patent covering numerous aspects of the invention both independently and as an overall system.

Further, each of the various elements of the invention and claims may also be achieved in a variety of manners. Additionally, when used or implied, an element is to be understood as encompassing individual as well as plural structures that may or may not be physically connected. This disclosure should be understood to encompass each such variation, be it a variation of an embodiment of any apparatus embodiment, a method or process embodiment, or even merely a variation of any element of these. Particularly, it should be understood that as the disclosure relates to elements of the invention, the words for each element may be expressed by equivalent apparatus terms or method terms—even if only the function or result is the same. Such equivalent, broader, or even more generic terms should be considered to be encompassed in the description of each element or action.

Such terms can be substituted where desired to make explicit the implicitly broad coverage to which this invention is entitled. As but one example, it should be understood that all actions may be expressed as a means for taking that action or as an element which causes that action. Similarly, each physical element disclosed should be understood to encompass a disclosure of the action which that physical element facilitates. Regarding this last aspect, as but one example, the disclosure of a “mount” should be understood to encompass disclosure of the act of “mounting”—whether explicitly discussed or not—and, conversely, were there effectively disclosure of the act of “mounting”, such a disclosure should be understood to encompass disclosure of a “mount” and even a “means for “mounting.” Such changes and alternative terms are to be understood to be explicitly included in the description.

Any patents, publications, or other references mentioned in this application for patent are hereby incorporated by reference. Any priority case(s) claimed by this application is hereby appended and hereby incorporated by reference. In addition, as to each term used it should be understood that unless its utilization in this application is inconsistent with a broadly supporting interpretation, common dictionary definitions should be understood as incorporated for each term and all definitions, alternative terms, and synonyms such as contained in the Random House Webster's Unabridged Dictionary, second edition are hereby incorporated by reference. Finally, all references listed below or other information statement filed with the application are hereby appended and hereby incorporated by reference, however, as to each of the above, to the extent that such information or statements incorporated by reference might be considered inconsistent with the patenting of this/these invention(s) such statements are expressly not to be considered as made by the applicant(s).

### I. US Patents

| Patent | Issue Date | Inventor/ |
|---|---|---|
| Number | year/month/day | Applicant |
| 4,111,188 | 1978-09-05 | Murphy, Jr. |
| 4,429,872 | 1984-02-07 | Capachi |
| 4,966,631 | 1990-10-30 | Matlin et al. |
| 5,143,556 | 1992-09-01 | Matlin |
| 5,164,020 | 1992-11-17 | Wagner et al. |
| 5,228,644 | 1993-07-20 | Garriott et al. |
| 5,289,356 | 1994-02-22 | Winston |
| 5,344,496 | 1994-09-06 | Stern et al. |
| 5,497,587 | 1996-03-12 | Hirai et al. |
| 5,505,788 | 1996-04-09 | Dinwoodie |
| 5,537,991 | 1996-07-23 | Winston et al. |
| 5,571,338 | 1996-11-05 | Kadonome et al. |
| 5,706,617 | 1998-01-13 | Hirai et al. |
| 5,746,029 | 1998-05-05 | Ullman |
| 5,746,839 | 1998-05-05 | Dinwoddie |
| 6,058,930 | 2000-05-09 | Shingleton |
| 6,093,884 | 2000-07-25 | Toyomura et al. |
| 6,111,189 | 2000-08-29 | Garvison et al. |
| 6,201,180 B1 | 2001-03-13 | Meyer et al. |
| 6,207,889 | 2001-03-27 | Toyomura et al. |
| 6,269,596 B1 | 2001-08-07 | Ohtsuka et al. |
| 6,360,491 B1 | 2002-03-26 | Ullman |
| 6,465,724 B1 | 2002-10-15 | Garvison et al. |
| 6,467,916 B2 | 2002-10-22 | Winston |
| 6,501,013 B1 | 2002-12-31 | Dinwoodie |
| 6,534,703 B2 | 2003-03-18 | Dinwoodie |
| 6,670,541 B2 | 2003-12-30 | Nagao et al. |
| 6,672,018 B2 | 2004-01-06 | Shingleton |
| 6,784,360 B2 | 2004-08-31 | Nakajima et al. |
| 6,809,251 B2 | 2004-10-26 | Dinwoodie |
| 6,958,868 B1 | 2005-10-25 | Pender |
| 6,959,517 B2 | 2005-11-01 | Poddany et al. |
| 6,987,604 B2 | 2006-01-17 | Rabinowitz et al. |
| 7,156,088 B2 | 2007-01-02 | Luconi |
| 7,388,146 B2 | 2008-06-17 | Fraas et al. |
| 7,406,800 B2 | 2008-08-05 | Cinnamon et al. |
| D510315 S | 2005-10-04 | Shugar et al. |
| D519444 S | 2006-04-25 | Mascolo |
| RE38988 E | 2006-02-28 | Dinwoodie |
| 07043884 B2 | 2006-05-16 | Moreno |

### II. US Patent Application Publications

| Publcation | Pub Date | Inventor/ |
|---|---|---|
| Number | year/month/day | Applicant |
| 20020066235 A1 | 2002-06-06 | Stearns et al. |
| 20030015637 A1 | 2003-01-23 | Liebendorfer |
| 20030070368 A1 | 2003-04-17 | Shingleton |
| 20040163338 A1 | 2004-08-26 | Liebendorfer |
| 20060054212 A1 | 2006-03-16 | Fraas et al. |
| 20070272234 A1 | 2007-11-29 | Allen et al. |
| 20040007260 A1 | 2004-01-15 | Dinwoodie |
| 20070102036 A1 | 2007-05-10 | Cinnamon |
| 20070144575 A1 | 2007-06-28 | Mascolo et al. |
| 20070151594 A1 | 2007-07-05 | Mascolo et al. |
| 20070295392 A1 | 2007-12-27 | Cinnamon |
| 20070295393 A1 | 2007-12-27 | Dinnamon |
| 20090078299 A1 | 2009-03-26 | Cinnamon et al. |

### III. Foreign Patent Documents

| | Pub/Issue Date | |
|---|---|---|
| Pub./Patent Number | Year/month/day | Inventor/Applicant |
| WO2007038760 A2 | 2007-04-05 | Thompson, Daniel S. et al. |
| DE29703481 U1 | 1997-02-26 | Ackmann und Kollegen |
| JP2000064523 | 2000-02-29 | Misawa Homes Co. Ltd. |

### IV. Non-Patent Literature Documents

www.thompsontec.com; Flush Mount Rail System, Technical
Specifications; 2008; 2 pgs
http://www.quickmountpv.com/products.php; Quick Mount PV
Products; Manufacturer of Waterproof Mounts for the PV Industry;
1 pg.
http://www.ttisolar.com/products/flatjack_order.html; Flat Jack
Roof Mount Order Form; 2 pgs
www.quickmountpv.com; Installation Instructions; 1 pg; 2009
Solar Power System Installation Manual; SRS Mounting System,
Rectantular Modules; Sharp Electronics Corp., 44 pages
http://www.we-llc.com/WEEB_howitworks.html; Bonding a PV
module to an anodized aluminum frame using the WEEB; 1 page
www.thompsontec.com; Flat Jack, Technical Specifications; 2008;
2 pgs
United States Provisional Application Number 61/195780, filed
Oct. 11, 2008, entitled Roof Mounted Solar Panel Support
System
United States Provisional Application Number 61/214857, filed
Apr. 28, 2009, entitled Roof Mounted Solar Panel Support System
United States Provisional Application Number 61/208323, filed
Feb. 23, 2009 Roof Mounted Solar Panel Support System

Thus, the applicant(s) should be understood to have support to claim and make a statement of invention to at least: i) each of the solar panel support devices as herein disclosed and described, ii) the related methods disclosed and described, iii) similar, equivalent, and even implicit variations of each of these devices and methods, iv) those alternative designs which accomplish each of the functions shown as are disclosed and described, v) those alternative designs and methods which accomplish each of the functions shown as are implicit to accomplish that which is disclosed and described, vi) each feature, component, and step shown as separate and independent inventions, vii) the applications enhanced by the various systems or components disclosed, viii) the resulting products produced by such systems or components, ix) each system, method, and element shown or described as now applied to any specific field or devices mentioned, x) methods and apparatuses substantially as described hereinbefore and with reference to any of the accompanying examples, xi) the various combinations and permutations of each of the elements disclosed, xii) each potentially dependent claim or concept as a dependency on each and every one of the independent claims or concepts presented, and xiii) all inventions described herein.

With regard to claims whether now or later presented for examination, it should be understood that for practical reasons and so as to avoid great expansion of the examination burden, the applicant may at any time present only initial claims or perhaps only initial claims with only initial dependencies. The office and any third persons interested in potential scope of this or subsequent applications should understand that broader claims may be presented at a later date in this case, in a case claiming the benefit of this case, or in any continuation in spite of any preliminary amendments, other amendments, claim language, or arguments presented, thus throughout the pendency of any case there is no intention to disclaim or surrender any potential subject matter. It should be understood that if or when broader claims are presented, such may require that any relevant prior art that may have been considered at any prior time may need to be re-visited since it is possible that to the extent any amendments, claim language, or arguments presented in this or any subsequent application are considered as made to avoid such prior art, such reasons may be eliminated by later presented claims or the like. Both the examiner and any person otherwise interested in existing or later potential coverage, or considering if there has at any time been any possibility of an indication of disclaimer or surrender of potential coverage, should be aware that no such surrender or disclaimer is ever intended or ever exists in this or any subsequent application. Limitations such as arose in Hakim v. Cannon Avent Group, PLC, 479 F.3d 1313 (Fed. Cir 2007), or the like are expressly not intended in this or any subsequent related matter. In addition, support should be understood to exist to the degree required under new matter laws—including but not limited to European Patent Convention Article 123(2) and United States Patent Law 35 USC 132 or other such laws—to permit the addition of any of the various dependencies or other elements presented under one independent claim or concept as dependencies or elements under any other independent claim or concept. Further any dependency claim amendment to the claims listed herein are hereby supported to be amended to include another claim dependency. In drafting any claims at any time whether in this application or in any subsequent application, it should also be understood that the applicant has intended to capture as full and broad a scope of coverage as legally available. To the extent that insubstantial substitutes are made, to the extent that the applicant did not in fact draft any claim so as to literally encompass any particular embodiment, and to the extent otherwise applicable, the applicant should not be understood to have in any way intended to or actually relinquished such coverage as the applicant simply may not have been able to anticipate all eventualities; one skilled in the art, should not be reasonably expected to have drafted a claim that would have literally encompassed such alternative embodiments.

Further, if or when used, the use of the transitional phrase “comprising” is used to maintain the “open-end” claims herein, according to traditional claim interpretation. Thus, unless the context requires otherwise, it should be understood that the term “comprise” or variations such as “comprises” or “comprising”, are intended to imply the inclusion of a stated element or step or group of elements or steps but not the exclusion of any other element or step or group of elements or steps. Such terms should be interpreted in their most expansive form so as to afford the applicant the broadest coverage legally permissible.

Finally, any claims set forth at any time are hereby incorporated by reference as part of this description of the invention, and the applicant expressly reserves the right to use all of or a portion of such incorporated content of such claims as additional description to support any of or all of the claims or any element or component thereof, and the applicant further expressly reserves the right to move any portion of or all of the incorporated content of such claims or any element or component thereof from the description into the claims or vice-versa as necessary to define the matter for which protection is sought by this application or by any subsequent continuation, division, or continuation-in-part application thereof, or to obtain any benefit of, reduction in fees pursuant to, or to comply with the patent laws, rules, or regulations of any country or treaty, and such content incorporated by reference shall survive during the entire pendency of this application including any subsequent continuation, division, or continuation-in-part application thereof or any reissue or extension thereon.

1. An efficient installment modularized solar power system comprising:
a plurality of solar module anchors secured to an area;
a plurality of elastic solar panel couplings connected to said solar module anchors;
a visual engagement confirmation element of said elastic solar panel couplings connected to said solar module anchors; and
a plurality of solar panel modules elastically attached to said elastic solar panel couplings.

2. An efficient installment modularized solar power system as described in claim 1 wherein said plurality of said elastic solar panel couplings comprises a direct solar panel connector between said solar module anchors and said solar panel modules.

3. An efficient installment modularized solar power system as described in claim 2 wherein said direct solar panel connector between said solar module anchors and said solar panel modules comprises a complete elastic constraint of said solar module anchors.

4. An efficient installment modularized solar power system as described in claim 1 further comprising a plurality of edge positioners each attached to one of said elastic solar panel couplings.

5. An efficient installment modularized solar power system as described in claim 4 wherein said plurality of edge positioners each attached to one of said elastic solar panel couplings comprises a plurality of integral clip edge positioners each attached to one of said elastic solar panel couplings.

6. An efficient installment modularized solar power system as described in claim 5 wherein said plurality of integral clip edge positioners each attached to one of said elastic solar panel couplings comprises a slide positioner.

7. An efficient installment modularized solar power system as described in claim 1 further comprising a plurality of insertion bias elements each attached to one of said elastic solar panel couplings.

8. An efficient installment modularized solar power system as described in claim 7 wherein said plurality of said insertion bias elements each attached to one of said elastic solar panel couplings comprises an elastic tongue.

9. An efficient installment modularized solar power system as described in claim 8 wherein said elastic tongue comprises a bottom tongue.

10. An efficient installment modularized solar power system as described in claim 9 wherein said bottom tongue comprises a clip opposing element.

11. An efficient installment modularized solar power system as described in claim 1 wherein said plurality of elastic solar panel couplings comprises an audible engagement confirmation element.

12. (canceled)

13. An efficient installment modularized solar power system as described in claim 1 herein said audible engagement element comprises a snap clip.

14. An efficient installment modularized solar power system as described in claim 13 wherein said snap clip comprises an elastic top retainer.

15. An efficient installment modularized solar power system as described in claim 1 wherein said plurality of solar module anchors secured to said area comprises a rail slide element.

16. An efficient installment modularized solar power system as described in claim 15 wherein said rail slide element comprises a rail slider fastener.

17. (canceled)

18. An efficient installment modularized solar power system as described in claim 1 wherein said plurality of elastic solar panel couplings comprises a detachable elastic top retainer.

19. An efficient installment modularized solar power system as described in claim 18 further comprising a rail mount connected to each of said elastic solar panel couplings and a vertical retainer of said plurality of elastic solar panel couplings.

20. An efficient installment modularized solar power system as described in claim 19 wherein said vertical retainer of said rail mount comprises an integral edge positioner.

21. An efficient installment modularized solar power system as described in claim 1 wherein said plurality of elastic solar panel couplings comprises a side flex retainer.

22-148. (canceled)

149. A method of efficiently installing a modularized solar power system comprises the step of :
securing a plurality of solar module anchors to an area;
providing a plurality of solar panel modules;
completely elastically attaching said solar panel modules; and
visually confirming engagement of said solar panels modules to an attachment system.

150-296. (canceled)
